(19) United States
(12) Patent Application Publication
(10) Pub. No.: US 2024/0107790 A1
(43) Pub. Date: Mar. 28, 2024

(54) OPTOELECTRONIC DEVICE

(71) Applicant: TCL TECHNOLOGY GROUP CORPORATION, Huizhou (CN)

(72) Inventors: Yixing YANG, Huizhou (CN); Tianfeng WANG, Huizhou (CN); Likuan ZHOU, Huizhou (CN); Yiran YAN, Huizhou (CN)

(21) Appl. No.: 18/270,663

(22) PCT Filed: Dec. 29, 2021
(86) PCT No.: PCT/CN2021/142735

§ 371 Date: Jun. 30, 2023

(30) Foreign Application Priority Data
Dec. 31, 2020 (CN) 202011638169.1

(51) Int. Cl. H10K 50/115; C09K 11/88; H10K 85/10

(52) U.S. Cl. CPC H10K 50/115; C09K 11/883; H10K 85/115; H10K 85/151; H10K 2101/40

(57) ABSTRACT

The present application discloses an optoelectronic device, including an anode, a hole transport layer disposed on the anode, a quantum dot light-emitting layer disposed on the hole transport layer, and a cathode disposed on the quantum dot light-emitting layer; the quantum dot light-emitting layer includes a quantum dot material in a core-shell structure, and a difference between a top energy level of a valence band of an outer shell layer material of the quantum dot material and that of a hole transport material in the hole transport layer is greater than or equal to 0.5 eV.

### CROSS-REFERENCE TO RELATED APPLICATIONS

This application is the national phase entry of International Application No. PCT/CN2021/142735, filed on Dec. 29, 2021, which is based upon and claims priority to the Chinese Patent Application No. 202011638169.1, filed on Dec. 31, 2020, the entire contents each of which are incorporated herein by reference.

### TECHNICAL FIELD

The present application relates to the field of display technology, and more particularly to an optoelectronic device.

### BACKGROUND

The statements herein provide only background information relevant to the present application and do not necessarily constitute the prior art. Quantum dot light-emitting display technology (QLED) is a new display technology that has emerged rapidly in recent years. QLED is similar to organic light-emitting display (OLED), which is an active light-emitting technology, and therefore also has the advantages of high luminous efficiency, fast response time, high contrast ratio, wide viewing angle, etc. Due to the excellent material properties of quantum dots in QLED display technology, QLED has more performance advantages than OLED in many aspects, such as quantum dots are continuously adjustable and have a very narrow luminous width, which can achieve a wider color gamut and higher purity display; the inorganic material properties of quantum dots make QLED have better device stability; QLED device drive voltage is lower than OLED, which can achieve higher brightness and lower energy consumption. The drive voltage of QLED devices is lower than that of OLEDs, enabling higher brightness and lower energy consumption; at the same time, QLED display technology matches the production process and technology of printed displays, enabling efficient mass production preparation with large size, low cost, and rollability. Therefore, QLED is considered to be one of the preferred technologies for future thin, portable, flexible, transparent, and high-performance next-generation display screens.

Due to the similarity of QLED and OLED display technology in terms of light-emitting principle, the device structure of QLED is more based on OLED display technology in the development process of QLED display technology, except that the light-emitting layer material is replaced by organic light-emitting materials and quantum dot materials, other functional layer materials such as charge injection layer or charge transfer layer are often used in OLED. materials that are already available. At the same time, the interpretation of device physics, the selection and matching principles of energy levels of functional layer materials, etc. in QLED devices also follow the existing theoretical system in OLEDs. Applying the classical device physics conclusions obtained in OLED device research to the QLED device system has indeed significantly improved the performance of QLED devices, especially the efficiency of QLED devices.

However, the classical ideas and strategies currently developed in OLEDs are unable to achieve an effective improvement in the service life of the QLED device, and although the classical ideas and strategies of OLED devices can improve QLED device efficiency, it has been found that the service life of these efficient QLED devices is significantly worse than that of similar devices with lower efficiency. Therefore, the existing QLED device structures designed based on the theoretical system of OLED devices do not improve the photovoltaic efficiency and lifetime performance of QLED devices at the same time. For the unique device mechanism of the QLED device system, new and more targeted new QLED device structures need to be developed.

### SUMMARY

An objective of the embodiments of the present application is to provide an optoelectronic device, aiming to solve the problem that it is difficult to improve the photovoltaic efficiency and lifetime performance of QLED devices at the same time in related technologies.

To solve the above technical problems, the technical proposals adopted in the embodiments of the present application are:

In a first aspect, there is provided an optoelectronic device including: an anode, a hole transport layer on the anode, a quantum dot light-emitting layer on the hole transport layer and a cathode on the quantum dot light-emitting layer, the quantum dot light-emitting layer includes a quantum dot material in a core-shell structure, and the quantum dot material has a top energy level difference between a valence band of a shell layer material and a valence band of a hole transport material in the hole transport layer is greater than or equal to 0.5 eV.

The beneficial effect of the optoelectronic device provided by the embodiment of the present application is that a top energy level difference greater than or equal to 0.5 eV is constructed between the outer shell layer material and the hole transport material of the quantum dot material, namely, E_{EML-HTL}≥0.5 eV. The hole injection efficiency is reduced by increasing the hole injection potential barrier, thereby balancing the hole and electron injection balance in the light-emitting layer. In addition, the hole injection barrier of ΔE_{EML-HTL}≥0.5 eV in the present application does not lead to an inability of hole injection, because the energy level of the outer shell layer of quantum dots under the energized operating state will undergo energy band bending, and carriers can be injected through the tunneling effect; thus, although this increase in the energy level barrier will cause a decrease in the carrier injection rate, it will not completely prevent the final carrier injection.

### BRIEF DESCRIPTION OF THE DRAWINGS

In order to more clearly illustrate the technical proposals in the embodiments of the present application, the following will briefly introduce the accompanying drawings that need to be used in the embodiments or exemplary technical descriptions. Obviously, the accompanying drawings in the following descriptions are only for some embodiments of the present application, those of ordinary skill in the art can also obtain other drawings based on these drawings without making creative efforts.

FIG. 1 is a schematic diagram of the structure of the optoelectronic device provided in the first aspect of the present application;

FIG. 2 is a schematic diagram of the structure of the optoelectronic device provided in the second aspect of the present application;

FIG. 3 is a schematic diagram of the structure of the optoelectronic device provided in the third aspect of the present application;

FIG. 4 is a schematic diagram of the structure of the optoelectronic device provided in the fourth aspect of the present application;

FIG. 5 is a schematic diagram of the structure of the optoelectronic device provided in the fifth aspect of the present application;

FIG. 6 is a schematic diagram of the structure of the optoelectronic device provided in the sixth aspect of the present application;

FIG. 7 is a schematic diagram of the structure of the optoelectronic device provided in the seventh aspect of the present application;

FIG. 8 is a schematic diagram of the structure of the optoelectronic device provided in the eighth aspect of the present application;

FIG. 9 is a schematic diagram of the structure of the optoelectronic device provided in the ninth aspect of the present application;

FIG. 10 is a schematic diagram of the structure of the optoelectronic device provided in the tenth aspect of the present application;

FIG. 11 is a schematic diagram of the structure of the optoelectronic device provided in the eleventh aspect of the present application;

FIG. 12 is a schematic diagram of the structure of the optoelectronic device provided in the twelfth aspect of the present application;

FIG. 13 is a schematic diagram of the structure of the optoelectronic device provided in the thirteenth aspect of the present application;

FIG. 14 is a schematic diagram of the regular structure of the quantum dot light-emitting diode provided by an embodiment of the present application;

FIG. 15 is a schematic diagram of the reverse structure of the quantum dot light-emitting diode provided by an embodiment of the present application;

FIG. 16 is a test chart of the luminous lifetime of quantum dot light-emitting diode provided in Examples 1 to 7 of the present application;

FIG. 17 is a test chart of the luminous lifetime of quantum dot light-emitting diode provided in Examples 8 to 9 of the present application;

FIG. 18 is a test chart of the luminous lifetime of quantum dot light-emitting diode provided in Examples 10 to 11 of the present application;

FIG. 19 is a graph of the variation of voltage versus time for the quantum dot light-emitting diode provided in Examples 12 to 14 of the present application;

FIG. 20 is a graph of the variation of voltage versus time for the quantum dot light-emitting diode provided in Examples 15 to 19 of the present application;

FIG. 21 is a test chart of the luminous lifetime of quantum dot light-emitting diode provided in Examples 20 to 25 of the present application;

FIG. 22 is a test chart of the luminous lifetime of quantum dot light-emitting diode provided in Examples 26 to 28 of the present application;

FIG. 23 is a test chart of the luminous lifetime of quantum dot light-emitting diode provided in Examples 29 to 31 of the present application;

FIG. 24 is a test chart of the luminous lifetime of quantum dot light-emitting diode provided in Examples 32 to 35 of the present application;

FIG. 25 is a test chart of the luminous lifetime of quantum dot light-emitting diode provided in Examples 36 to 38 of the present application;

FIG. 26 is a graph of the variation of voltage versus time for the quantum dot light-emitting diode provided in Examples 39 to 41 of the present application;

FIG. 27 is a test chart of the luminous lifetime of quantum dot light-emitting diode provided in Examples 39 to 41 of the present application;

FIG. 28 is a graph of the variation of voltage versus time for the quantum dot light-emitting diode provided in Examples 42 to 43 of the present application; and

FIG. 29 is a test chart of the luminous lifetime of quantum dot light-emitting diode provided in Examples 42 to 43 of the present application;

### DETAILED DESCRIPTION OF THE EMBODIMENTS

In order to make the technical problem to be solved, technical proposals, and beneficial effects in the present application clearer, the present application will be described in further detail in conjunction with the accompanying drawings and the embodiments. It should be understood that the specific embodiments described here are only used to explain the present application, not to limit the present application.

In the present application, the term “and/or”, which describes the association relationship of the associated objects, indicates that three relationships can exist, for example, A and/or B, which can indicate: the presence of A alone, the presence of both A and B, and the presence of B alone. Where A, B can be singular or plural.

In the present application, the term “and/or”, which describes the association relationship of the associated objects, indicates that three relationships can exist, for example, A and/or B, which can indicate: the presence of A alone, the presence of both A and B, and the presence of B alone. Where A, B can be singular or plural.

In the present application, “at least one” means one or more, and “a plurality of” means two or more. “At least one of the following”, or the like, refers to any combination of these items, including any combination of single or plural items. For example, “at least one of a, b, or c”, or “at least one of a, b, and c”, can mean: a, b, c, a-b (i.e., a and b), a-c, b-c, or a-b-c, where a. b, c can be single or multiple, respectively.

It should be understood that in various embodiments of the present application, the size of the serial numbers of the above processes does not imply the order of execution, and some or all of the steps may be performed in parallel or sequentially, and the order of execution of the processes shall be determined by their function and inherent logic, and shall not constitute any limitation to the processes implemented in the embodiments of the present application. The terms used in the embodiments of the present application are used solely for the purpose of describing a particular embodiment and are not intended to limit the present application. The singular forms of “a” and “the” as used in the embodiments of the present application and the appended claims are also intended to include the plural forms, unless the context clearly indicates otherwise.

In the embodiment of the present application, ΔE_{HTL-HIL}=E_{HOMO, HTL}-E_{HIL}, ΔE_{EML-HTL}=E_{HOMO, EML}-E_{HTL}, and all energy level/function values are taken as absolute values, with a large absolute value of energy level indicating a deep energy level and a small absolute value of energy level indicating a shallow energy level.

The key to the present application is to improve both the lifetime and photovoltaic efficiency of QLED devices. Currently, there is a significant difference between device lifetime testing and device efficiency characterization: device efficiency testing is usually conducted for a short period of time and therefore characterizes the instantaneous state of the QLED device at the start of the operation, while device lifetime characterizes the ability to maintain device efficiency after the device continues to operate and enters a steady state.

At present, based on the existing theoretical system of traditional OLED devices, it is believed that the injection rate of electrons into the light-emitting layer is usually faster than that of holes. Therefore, in order to balance and improve the recombination efficiency of holes and electrons in the light-emitting layer of QLED devices, a hole injection layer is usually introduced in the device, and the injection barrier between two adjacent functional layers is minimized to enhance the injection efficiency of holes, thereby improving carrier injection efficiency and reducing interface charge accumulation. However, this method can only improve the optoelectronic efficiency at the initial moment of the QLED device to a certain extent, but it cannot improve the device life at the same time, or even reduce the device lifetime. Through the gradual development and in-depth research on the mechanism of QLED devices, the present application found that due to the use of quantum dot materials and other nanomaterials with special material surfaces in the QLED device system, QLED has some special mechanisms different from OLED device systems. This mechanism is closely related to the performance of QLED devices, especially the device life.

Specifically, the present application has found through research that: when the QLED device is in the initial working state, the injection rate of electrons in the light-emitting layer is faster than that of holes, causing the quantum dot material to be negatively charged, and this negative state will be maintained due to the structural characteristics of quantum dot material and the surface ligand binding effect, Coulomb blocking effect and other factors. However, the negatively charged state of the quantum dot material makes the injection of electrons more and more difficult during the continuous operation of the QLED device, resulting in an imbalance between the actual injection of electrons and holes in the light-emitting layer. When the QLED device continues to light up and work until a stable state, the negatively charged state of the quantum dot material also tends to be stable, that is, the electrons newly captured and bound by the quantum dots and the electrons consumed by the radiative transition reach a dynamic balance. At this time, the injection rate of electrons into the light-emitting layer is much lower than that in the initial state, and the hole injection rate required to achieve the balance of charge injection in the light-emitting layer is relatively low. If the hole injection efficiency is still improved based on the theoretical system of traditional OLED devices, the use of a deep-level hole transport layer can only form an instantaneous balance of charge injection in the initial operation stage of QLED device, and achieve high device efficiency at the initial instant. However, as the QLED device enters a stable working state, excessive hole injection will instead aggravate the imbalance between electrons and holes in the light-emitting layer of the device, and the efficiency of the QLED device cannot be maintained and will decrease accordingly. And this charge imbalance will continue to intensify as the device continues to work, resulting in a corresponding rapid decline in the life of the QLED device.

Therefore, in order to achieve a balance of carrier injection in the light-emitting layer of the device and obtain a device with higher efficiency and longer service life, the key to fine-tuning the carrier injection of holes and electrons on both sides of the device is: on the one hand, adjust the hole injection rate to a lower rate, balance the hole injection rate and the electron injection rate in the stable working state of the QLED device, and improve the recombination efficiency of the QLED device. On the other hand, because the hole injection rate required by QLED devices in the actual stable working state is lower than traditional expectations, carrier accumulation is prone to occur, causing irreversible damage to the device. Therefore, it is necessary to avoid the influence of carrier accumulation on the lifetime of the device as much as possible, so as to improve the lifetime of the device.

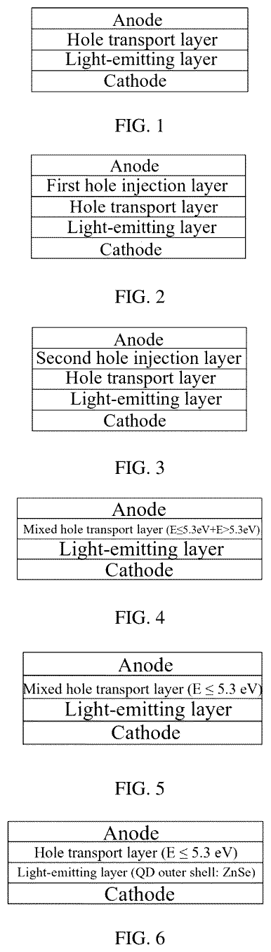

As shown in FIG. 1, the first aspect of the embodiment of the present application provides an optoelectronic device, including: an anode, a hole transport layer on the anode, a quantum dot light-emitting layer on the hole transport layer, and a cathode on the quantum dot light-emitting layer, the quantum dot light-emitting layer includes a quantum dot material with a core-shell structure, and the difference between the top energy level of the valence bands of the shell material of the quantum dot material and the hole transport material in the hole transport layer is greater than or equal to 0.5 eV.

The optoelectronic device provided in the first aspect of the present application constructs a top energy level difference between the valence bands greater than or equal to 0.5 eV, namely E_{EML-HTL}≥0.5 eV, between the outer shell layer material of the quantum dot material and the hole transport material. The hole injection efficiency is reduced by increasing the hole injection potential barrier, thus balancing the hole and electron injection balance in the light-emitting layer. Based on the energy level properties of current hole transport materials and the energy level properties of the shell materials of quantum dot materials, the present application finds that an energy level barrier of at least ΔE_{EML-HTL}≥0.5 eV is required to achieve a significant reduction in the hole injection efficiency and to balance the electron and hole injection efficiency in the light-emitting layer. In addition, the hole injection potential barrier of ΔE_{EML-HTL}≥0.5 eV in the present application does not lead to the inability of hole injection, because the energy level of the outer shell layer of quantum dots will undergo energy band bending in the energized operating state, and carriers can be injected through the tunneling effect; thus, although this increase in the energy level potential barrier will cause a decrease in the carrier injection rate, it will not completely prevent the final carrier injection.

Quantum dot materials generally comprise semiconductor compounds, such as elements from the groups of II-IV, II-VI, II-V, III-V, III-VI, IV-VI, I-III-VI, II-IV-VI, II-IV-V in the periodic table, or includes a core-shell structure including at least two of the above-mentioned semiconductor compounds. In some embodiments, the core-shell structure of the quantum dot material includes a core and a shell layer. In other embodiments, the quantum dot material with the core-shell structure includes a core, an outer shell layer, and an intermediate bridge layer disposed between the core and the outer shell layer, and the intermediate bridge layer may be a single layer or multiple layers. The core material in the core-shell quantum dot material determines the luminescence performance, and the shell material plays a role in protecting the luminescence stability of the core and facilitating carrier injection, electrons and holes are injected into the core through the outer shell layer to emit light. Generally, the band gap of the core is narrower than the shell, so the valence band energy difference between the hole transport material and quantum dot core is smaller than that between the hole transport material and quantum dot shell layer. Therefore, the ΔE_{EML-HTL} in the embodiment of the present application greater than or equal to 0.5 eV can ensure the effective injection of hole carriers into the core of the quantum dot material at the same time. The specific structures and specific materials of quantum dot materials for the core-shell structure of the embodiments of the present application are described in detail in the later embodiments according to different application scenarios.

In some embodiments, the top energy level difference between the valence bands of the outer shell layer material of the quantum dot material and the hole transport material in the hole transport layer is 0.5 eV-1.7 eV, i.e., ΔE_{EML-HTL} is 0.5 eV-1.7 eV. The energy level barrier in this range between the outer shell layer material of the quantum dot material and the hole transport material can be applied to devices constructed from different hole transport materials and quantum dot materials to optimize the electron-hole injection balance in different device systems. In practical applications, different top energy level differences in the valence bands, ΔEEML-HTL, can be set according to the specific material properties to finely regulate the carrier injection rates of holes and electrons on both sides of the light-emitting layer, so that the hole and electron injection can be balanced.

In some specific embodiments, the difference between the band top energy level of the valence bands of the outer shell layer material of the quantum dot material and the hole transport material is 0.5 eV-0.7 eV. Here, the hole transport material may be TFB, P12, and P15, and the quantum dot shell material is ZnSe, CdS, such as device systems like TFB-ZnSe, P12/P15-CdS, etc.

In some specific embodiments, the difference between the top energy level of the valence bands of the outer shell layer material of the quantum dot material and the hole transport material is 0.7 eV-1.0 eV, when the hole transport material can be used as TFB, P09, and the quantum dot shell material is ZnSe, CdS, such as the device system of P09-ZnSe, TFBCdS and the like.

In some specific embodiments, the difference between the top energy level of the valence bands of the outer shell layer material of quantum dot material and hole transport material is 1.0 eV-1.4 eV, here, the hole transport material may be TFB, P09, P13, P14, and the quantum dot shell material is CdS, ZnSe, ZnS, such as device system of TFB-ZnS, P09-CdS, P13/P14-ZnSe, and the like.

In some specific embodiments, the difference between the top energy level of the valence bands of the outer shell layer material and the hole transport material of the quantum dot material is greater than 1.4 eV-1.7 eV, and the device systems such as P09-ZnS, P13/P14-ZnS can be used.

Considering from one aspect, since the hole injection layer in the current devices is often to improve the hole injection efficiency, and in some embodiments of the present application, the QLED device needs to regulate the hole injection to a lower rate by certain means. Therefore, in some specific embodiments, the hole injection layer may be omitted in the optoelectronic device provided in the first aspect of the embodiments of the present application.

On the other hand, the introduction of the hole injection layer in the QLED device not only improves the hole injection efficiency, but also regulates the smooth and balanced hole injection, which is one of the key performance factors affecting the performance and lifetime of the device. Therefore, in an embodiment of the present application, the hole injection efficiency in the device can also be regulated and the impact of charge accumulation on the device lifetime can be reduced by setting a hole injection layer in the device. Specifically:

Usually, in the study of QLED device performance, more attention is paid to the interface damage caused by charge accumulation on both sides of the EML, such as the HTL or ETL interface, and to the quenching of excitons in the EML emitting layer. However, in fact, the interface energy level barrier between HIL and HTL is also easy to form charge accumulation, so that the interface between HIL and HTL is irreversibly destroyed under the electric field, resulting in a rise in the device voltage and decay of the device brightness. Moreover, the cause of the voltage rise of the QLED device here is significantly different from the voltage rise caused by the charge accumulation at the EML interface as follows: the damage caused by the electric field at the interface between HIL and HTL is usually irreversible due to the charge accumulation, and the damage can continue to occur as the device continues to be energized, i.e., it will continue to deteriorate; whereas the charge accumulation at the EML interface is reversible and will reach a certain degree of saturation. Therefore, the charge accumulation at the interface between HIL and HTL has a greater impact on the performance of the device such as lifetime.

On the one hand, some embodiments of the present application optimize the carrier and recombination efficiency of carriers in the QLED device in order to reduce irreversible damage to the device lifetime caused by charge accumulation at the HIL and HTL interface. As shown in the attached FIG. 2, a second aspect of the embodiments of the present application provides an optoelectronic device on the basis of the above embodiment of the first aspect or separately, the optoelectronic device includes a first hole injection layer, the first hole injection layer is located between the anode layer and the hole transport layer, and the absolute value of the difference between the top energy level of the valence band of the hole transport layer material and the work function of the first hole injection material in the first hole injection layer is less than or equal to 0.2 eV.

The optoelectronic device provided in the second aspect of the present application, by limiting |ΔE_{HTL-HIL}| less than or equal to 0.2 eV, enables the potential energy barrier of the hole injection between HTL and HIL to be significantly reduced, improves the efficiency of hole injection from the anode, facilitates the effective injection of holes from HIL to HTL, eliminates the potential barrier and the interface charge, reduces the overall resistance of the device, and thus reduces the irreversible damage caused by the charge accumulation at the interface between HIL and HTL. This reduces the drive voltage of the device, and improves the device's lifetime. If |ΔE_{HTL-HIL}| is greater than 0.2 eV, the potential energy barrier at the interface from HIL to HTL is prone to charge accumulation, which makes the interface between HIL and HTL irreversibly damaged by the electric field, causing the device voltage to rise and the device brightness to decay.

In some embodiments, the absolute value of the difference between the top energy level of the valence band of the hole transport layer material and the work function of the first hole injection material is 0 eV. The |ΔE_{HTL-HIL}| in these embodiments is 0, thus the effective injection of holes from HIL to HTL is good, the potential barrier and interface charge are eliminated, and the overall resistance of the device is reduced, thus reducing the device drive voltage and improving the device lifetime.

In some embodiments, the absolute value of the work function of the first hole injection material is 5.3 eV-5.6 eV, which is close to the absolute value of the valence band energy level of the current conventional hole transport material (around 5.4 eV), which is conducive to controlling the |ΔE_{HTL-HIL}| in a lower range, making the two energy basically equal and the barrier and interface charges being eliminated, reducing the device driving voltage and improving the device lifespan. By selecting the HIL and HTL materials with suitable energy levels, the |A_{HTL-HIL}| is less than or equal to 0.2 eV, which can effectively eliminate the potential energy barrier from HIL to HTL and the charge accumulation at the interface, thus reducing the irreversible damage caused at the interface between HIL and HTL.

In some embodiments, the mobility of the hole transport material is higher than 1×10⁻⁴ cm²/Vs. The embodiments of the present application use a hole transport material with a mobility higher than 1×10⁻⁴ cm²/Vs, and the inventor has found through extensive experiments that the use of the hole transport material with the above mobility can improve the hole transport and migration effect, prevent charge accumulation, eliminate interfacial charge, better reduce the device drive voltage, and improve the device life.

On the other hand, embodiments of the present application are designed to reduce the hole injection rate within the QLED device, regulate the carrier injection and recombination efficiency, and at the same time reduce the irreversible damage to the device lifetime caused by the charge accumulation at the HIL and HTL interfaces. As shown in FIG. 3, a third aspect of an embodiment of the present application provides an optoelectronic device on the basis of the above first aspect embodiment or separately, including a second hole injection layer, the second hole injection layer is located between the anode layer and the hole transport layer, and the difference between the top energy level of the valence band of the hole transport layer material in the hole transport layer and a work function of the second hole injection material in the second hole injection layer is less than −0.2 eV.

The optoelectronic device provided in the third aspect of the present application, by constructing an injection potential barrier less than −0.2 eV between the hole transport layer material and the second hole injection material, i.e., ΔE_{HTL-HIL}<−0.2 eV, increases the hole injection potential barrier from the anode to the HIL, thereby reducing the overall rate of hole injection within the QLED device and effectively controlling the number of holes entering the QLED device. On the one hand, it effectively reduces the rate of hole injection into the light-emitting layer to balance the hole and electron injection rate in the light-emitting layer and improve the carrier recombination efficiency; on the other hand, it avoids the formation of charge accumulation at the interface of HTL and HIL by excessive hole injection and prevents the irreversible destructive effect of the interface charge accumulation on the device lifetime. At the same time, the formation of a hole-blocking potential barrier from HTL to HIL prevents the diffusion of holes to the HIL layer, improves the utilization of holes, and ensures the effective “survival” of holes before they are injected into the light-emitting layer. This ensures that the carriers are injected in a balanced manner in the stable operating state of the device, and the injected holes are fully and effectively utilized to ensure the luminescence efficiency of the device and to achieve both the improvement of the device's efficiency and lifetime.

In some embodiments, the quantum dot material with a core-shell structure contained in the quantum dot light-emitting layer of the optoelectronic device has an top energy level difference between the valence bands of the outer shell layer material and the hole transport material greater than 0 eV, i.e., ΔE_{EML-HTL}>0, and the energy level of the light-emitting layer is deeper than that of the hole transport layer; here, there is an injection barrier between the hole transport layer material and the second hole injection material of less than −0.2 eV, i.e., ΔE_{HTL-HIL}−0.2 eV, the energy level of hole injection layer deeper than that of the hole transport layer. At this point, the light-emitting layer—hole transport layer—hole injection layer forms a “deep-shallow-deep” energy level structure, so that the holes injected into the hole transport layer form a hole carrier trap, effectively “store” the accumulated holes and do not spread to other functional layers or interfaces outside the HTL layer. In some specific embodiments, the quantum carrier trap in the HTL layer forms a hole carrier trap, which effectively “stores” the accumulated holes without spreading to other functional layers or interfaces other than the HTL layer, and eliminates the influence of the interface charge on the device. In some specific embodiments, the energy level difference between the top of the valence bands of the outer shell layer material of the quantum dot material and the hole transport material is greater than or equal to 0.5 eV; in some other specific embodiments, the energy level difference between the top of the valence bands of the outer shell layer material of the quantum dot material and the hole transport material can also be 0.5 eV-1.7 eV, i.e. ΔE_{EML-HTL} is 0.5 eV-1.7 eV, which is experimentally verified that the above hole carrier trap formed in the embodiment is effective, and in the practical application process, the hole carrier trap is used to more finely regulate the injection balance of holes and electrons in the light-emitting layer of the device and improve the carrier compound efficiency.

In some embodiments, the difference between the top energy level of the valence band of the hole transport layer material and the work function of the second hole injection material is from −0.9 eV to −0.2 eV, namely the difference of ΔE_{HTL-HIL} is from −0.9 eV to −0.2 eV, the above range has a good balance effect on the hole injection and transport. If lower than −0.9 eV, the hole injection resistance increases, leading to a decrease in hole injection, affecting the injection balance of holes and electrons in the light-emitting layer and effective recombination; if the potential barrier is greater than −0.2 eV, the holes are easy to form at the interface to accumulate, and the utilization rate is low.

In some embodiments, the absolute value of the work function of the second hole injection material is 5.4 eV-5.8 eV. The absolute value of the work function of the second hole injection material in the present application is 5.4 eV-5.8 eV, which aids in forming the hole-blocking barrier of −0.2 eV with the hole transport material. Specifically, the absolute value of the valence band of the conventional hole transport material is about 5.3-5.4 eV. The second hole injection material with an absolute value of the work function greater than or equal to 5.4 eV can form a negative energy level difference of less than −0.2 eV with the conventional hole transport material, thus forming a hole blocking barrier, optimizing the hole injection rate, and improving the hole utilization rate.

In some embodiments, the mobility of the hole transport material is higher than 1×10⁻⁴ cm²/Vs. The embodiments of the present application use a hole transport material with a mobility higher than 1×10⁻⁴ cm²/Vs to ensure the effect of hole transport and migration, prevent charge accumulation, eliminate interfacial charge, and better reduce the device drive voltage and enhance the device life.

In the above-mentioned second and third aspect embodiments of the present application, the hole injection material is selected from a metal oxide material. That is, in some specific embodiments, when the optoelectronic device includes a first hole injection layer, the first hole injection material in the first hole injection layer is selected from a first metal oxide material. In other specific embodiments, when the optoelectronic device includes a second hole injection layer, the second hole injection material in the second hole injection layer is selected from a second metal oxide material. In the above embodiments of the present application, the metal oxide material used for the hole injection material has better stability and is not acidic, which not only meets the requirements of the above embodiments for hole injection, but also does not adversely affect the adjacent functional layer. This avoids the decay of the organic hole injection material on the device life due to thermal or electrical effect destruction during the device operation, which also avoids the destructive effect of an acidic organic hole injection material on the adjacent functional layer.

In some embodiments, the first metal oxide material and the second metal oxide material independently include at least one metal nanomaterial of tungsten oxide, molybdenum oxide, vanadium oxide, nickel oxide, and copper oxide, respectively, these metal nanomaterials have better stability and are not acidic, which in the practical applications, by regulating the work function, can achieve the construction of different potential energy barriers with the hole transport layer, which in turn facilitate the regulation of hole injection and transport, improve carrier recombination efficiency, and reduce the impact of charge accumulation on device lifetime.

In some embodiments, the particle size of the first metal oxide material and the second metal oxide material are independently 2-10 nm. The small particle size of the metal oxide material is conducive to the deposition of films with dense layers and uniform thickness, which improves the bonding tightness with the adjacent functional layers and reduces the interfacial resistance, which is conducive to improving device performance.

In other embodiments, the hole injection material can also be an organic hole injection material such as poly(3,4-ethylenedioxythiophene)-polystyrene sulfonate (PEDOT:PSS), HIL2, HIL1-1, HIL1-2, copper phthalocyanine (CuPc), 2,3,5,6-tetrafluoro-7,7′,8,8′-tetracyanoquinone-dimethane (F4-TCNQ), 2,3,6,7,10. 11-hexacyano-1,4,5,8,9,12-hexaazatriphenylenehexacarbonitrile (HATCN), and the like. PEDOT:PSS includes an organic molecule having the structural formula of:

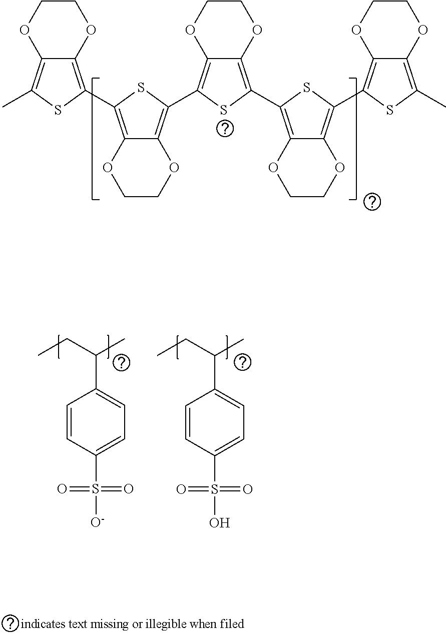

with a work function of −5.1 eV; HIL2 includes organic molecules having the structural formulae of:

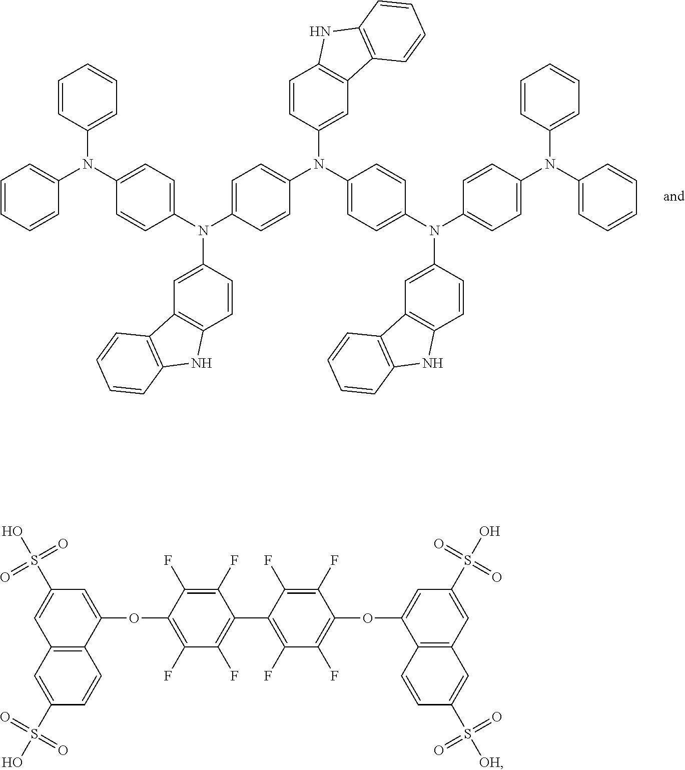 [SMILES: c1ccc(N(c2ccccc2)c2ccc(N(c3ccc(N(c4ccc(N(c5ccc(N(c6ccccc6)c6ccccc6)cc5)c5ccc6[nH]c7ccccc7c6c5)cc4)c4ccc5[nH]c6ccccc6c5c4)cc3)c3ccc4[nH]c5ccccc5c4c3)cc2)cc1 ; O=S(=O)(O)c1ccc2c(Oc3c(F)c(F)c(-c4c(F)c(F)c(Oc5cc(S(=O)(=O)O)cc6cc(S(=O)(=O)O)ccc56)c(F)c4F)c(F)c3F)cc(S(=O)(=O)O)cc2c1]

with a work function of −5.6 eV; HIL1-1 and HIL1-2 both include organic molecules having the structural formulae of:

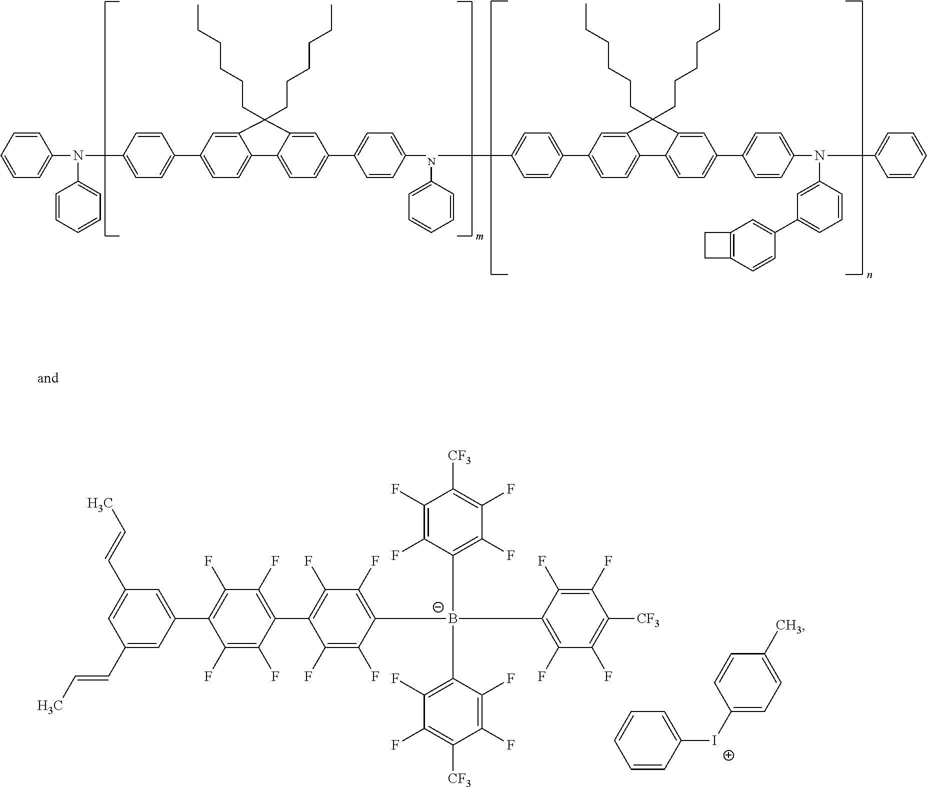

with a work function of HIL1-1 being −5.4 eV and a work function of HIL 1-2 being −5.3 eV.

In some embodiments, the thickness of the first hole injection layer is 10-150 nm, and in other embodiments, the thickness of the second hole injection layer is 10-150 nm. The thickness of the hole injection layer can be flexibly adjusted according to the actual application requirements, and the hole injection rate can be better adjusted by adjusting the thickness of the hole injection layer.

The embodiments of the present application are designed to construct an potential energy barrier with ΔE_{EML-HIL} greater than or equal to 0.5 eV to reduce the hole injection rate and regulate the carrier injection and recombination efficiency within the QLED device, while reducing irreversible damage to the device lifetime caused by charge accumulation at the HIL-HTL interface. As shown in FIG. 4, a fourth aspect of the present application provides an optoelectronic device, which contains at least two hole transport materials in the hole transport layer of the optoelectronic device, the absolute value of the top energy level of the valence band of at least one hole transport material is less than or equal to 5.3 eV. In a specific embodiment, the above at least two hole transport materials include at least one hole transport material having a top energy level of the valence band less than or equal to 5.3 eV and one hole transport material having an absolute value of the top energy level of the valence band greater than 5.3 eV.

The fourth aspect of the present application provides the hole transport layer of the optoelectronic device as a mixed material layer containing a plurality of hole transport materials having different energy levels of the valence band, the energy level of the top of the valence band of at least one hole transport material is less than or equal to 5.3 eV, while the energy level of the outer shell layer of conventional quantum dot light-emitting materials tends to be deeper (6.0 eV or deeper), thus making the hole transport material of shallow energy level and the quantum dot shell material forming an energy level difference greater than or equal to 0.5 eV. In addition, the hole transport material containing the absolute value of the top of the valence band greater than 5.3 eV can modulate the energy level difference between the hole transport material and the outer shell layer of the luminescent material in a small and finer way. This enables the fine regulation of the hole injection barrier between the hole transport material and the quantum dot shell layer through the cooperation of the shallow-energy-level hole transport material with the absolute value less than or equal to 5.3 eV and deep-energy-level hole transport material with the absolute value greater than 5.3 eV, as well as the regulation of the hole mobility in the HTL layer through hole transport materials of different energy levels. By increasing the hole injection barrier and decreasing the hole injection efficiency, the balance of hole and electron injection in the light-emitting layer can be improved and the device luminescence efficiency can be increased while reducing the impact of charge accumulation on the device lifetime.

In some embodiments, the hole transport layer of the optoelectronic device contains at least two hole transport materials, with one hole transport material having an absolute value of the top energy level of the valence band less than or equal to 5.3 eV, further includes a hole transport material with an absolute value of the top energy level of the valence band greater than 5.3 eV and less than 5.8 eV. In some embodiments, the hole transport layer includes at least two hole transport materials, with one hole transport material having an absolute value of the top energy level of the valence band less than or equal to 5.3 eV, further includes a hole transport material with an absolute value of the top energy level of the valence band greater than or equal to 5.8 eV. In other embodiments, the hole transport layer contains at least three hole transport materials, with one hole transport material having an absolute value of the top energy level of the valence band less than or equal to 5.3 eV, further includes a hole transport material with an absolute value of the top energy level of the valence band greater than 5.3 eV and less than 5.8 eV and a hole transport material having an absolute value of the top energy level of the valence band greater than or equal to 5.8 eV. In the embodiments of the present application, through the cooperation of the shallow energy level material and deep energy level material, can regulate the hole injection barrier so that the hole to the light-emitting material injection energy level barrier is greater than or equal to 0.5 eV and reduce the hole injection efficiency, so as to balance the injection balance of holes and electrons in the light-emitting layer according to the actual application requirements, device system, and other factors, therefore, the application is flexible and convenient.

In some embodiments, when the hole transport layer includes a hole transport material with an energy level of the top of the valence band greater than 5.3 eV less than 5.8 eV, the electron transport layer of the optoelectronic device may adopt at least one of an organic electron transport material layer, a metal oxide nanoparticle layer such as ZnO nanoparticles, and a sputter-deposited metal oxide layer. In the embodiment of the present application in which the hole transport layer includes at least one hole transport material with a top energy level of the valence band less than or equal to 5.3 eV and a hole transport material with a top energy level of the valence band greater than 5.3 eV and less than 5.8 eV, the hole transport layer has a more moderate top energy level of the valence band and hole mobility, so it can be better matched with conventional metal oxides such as ZnO or organic electron transport materials, which is conducive to the regulation of the charge balance of holes and electrons.

In some embodiments, when the hole transport layer includes a hole transport material with a top energy level of the valence band greater than or equal to 5.8 eV, the electron transport layer of the optoelectronic device can adopt metal oxide nanoparticles, selecting from metal oxide nanoparticles with fewer surface group connections. In the embodiment of the present application the hole transport layer includes a hole transport material having the energy level of the top of the valence band greater than 5.8 eV, both the energy level and mobility thereof have a large difference with the aforementioned hole transport material with the shallow energy level of the top of the valence band of less than or equal to 5.3 eV, thus, a continuous regulation over a large window range can be achieved through different mixing ratios, suitable for QLED device systems with significant changes in electron injection and transport from the initial state to continuous operation to steady state of the device, such as metal oxide nanoparticles with fewer surface group connections.

In some embodiments, the hole transport layer is a mixed material layer including hole transport materials of different energy levels, in which the hole transport material with the absolute value of the top energy level of the valence band less than or equal to 5.3 eV has a mass percentage content of 30%-90%; with the shallow-energy-level hole transport material of this percentage, it is easy to form a hole injection barrier greater than or equal to 0.5 eV with the outer shell layer of the light-emitting material. In practical applications, the mixing ratio of materials with different energy levels can be flexibly adjusted according to the depth of the energy levels of the materials. In some specific embodiments, when the mass percentage of the hole transport material whose absolute value of the energy level of the top of the valence band is less than or equal to 5.3 eV is 50%-60%, a good effect can be achieved.

In some embodiments, the hole transport layer is a mixed material layer containing hole transport materials of different energy levels, the mobility of at least one hole transport material is higher than 1×10⁻³ cm²/Vs. The high mobility of the hole transport materials in the present application ensures the transport and migration performance of the holes and reduces the accumulation of holes at the interface that affects the device's performance. In addition, the high hole mobility of the hole transport layer material has a relatively shallow top energy level of the valence band, which also ensures the formation of a suitable energy difference with the quantum dot shell material.

In some specific embodiments, the hole transport layer is a mixed material layer including hole transport materials of different energy levels, the mobility of at least one hole transport material is higher than 1×10⁻² cm²/Vs. In other specific embodiments, the hole transport layer is a mixed material layer including hole transport materials of different energy levels, the mobility of each hole transport material is higher than 1×10⁻³ cm²/Vs. The above embodiments of the present application optimize the mobility of the hole transport materials while ensuring the efficiency of hole migration to avoid charge accumulation affecting the device performance, and also ensure that the hole transport materials of different energy levels in the hole transport layer are matched to construct the hole injection barrier to ensure the formation of a potential energy barrier of ΔE_{EML-HTL} that is greater than or equal to 0.5 eV to optimize the carrier injection balance and recombination efficiency in the QLED device.

The embodiments of the present application are designed to construct a potential energy barrier of ΔE_{EML-HTL} that is greater than or equal to 0.5 eV, to achieve the purpose of reducing the hole injection rate and regulating the carrier injection and recombination efficiency within the QLED device, and at the same time reducing the irreversible damage to the device lifetime caused by the charge accumulation at the interface of HIL and HTL. As shown in FIG. 5, a fifth aspect of the embodiments of the present application provides an optoelectronic device, which includes at least two hole transport materials in the hole transport layer of the optoelectronic device, and the absolute value of the energy level of the top of the valence band of each hole transport material is less than or equal to 5.3 eV.

The hole transport layer of the optoelectronic device provided in the fifth aspect of the present application is a mixed material layer including a plurality of hole transport materials with different top energy levels of the valence band, in which the energy level of the top of the valence band of each hole transport material is less than or equal to 5.3 eV, and can form an energy level difference greater than or equal to 0.5 eV with the outer shell layer of the quantum dot light-emitting material which has a deeper energy level. This enables a finer regulation of the hole injection barrier between the quantum dot shell layer in the HTL and EML, so that the device has ΔE_{EML-HTL}≥0.5 eV, thus after the QLED device enters a stable working state, charge injection balance and device efficiency are maintained, and the lifetime of the device is optimized. In addition, the hole mobility of the mixed hole transport layer can also be finely regulated through different mixing ratios by using the different hole mobility of the hole transport layer materials that also have a shallow top energy level of the valence band.

In some embodiments, the hole transport layer includes a mixed material layer of hole transport materials of different energy levels, where the mass percent content of each hole transport material is 5%-95%. By mixing and matching the hole transport materials of different energy level depths and mobilities, the hole mobility and injection barrier of the mixed hole transport layer can be better regulated.

In some embodiments, the hole transport layer includes a mixed material layer of hole transport materials of different energy levels, where the mobility of at least one hole transport material is higher than 1×10⁻³ cm²/Vs, and the hole transport layer material with high hole mobility has a relatively shallow top energy level of the valence band. By limiting the mobility of the hole transport material, the high mobility ensures the hole transport and migration, while ensuring the formation of a more suitable injection barrier to avoid the accumulation of holes at the interface leading to compromised device performance. In some embodiments, the mobility of at least one hole transport material in the hole transport layer is higher than 1×10⁻² cm²/Vs. In some embodiments, the mobility of each hole transport material in the hole transport layer is higher than 1×10⁻³ cm²/Vs.

In some embodiments, when the energy level of the top of the valence band of the hole transport material in the hole transport layer is less than or equal to 5.3 eV, surface passivated metal oxide nanoparticles are used in the electron transport layer of the optoelectronic device, and the passivated metal oxide nanoparticles of which the surface is sufficiently modified are selected. In the embodiment of the present application, when the hole transport layer in the hole transport material has a top energy level of the valence band less than or equal to 5.3 eV, in order to correspond to materials with a small change in the electron injection and transport, it is suitable to select a QLED device system with less variance in electron injection and transport from the initial state to the continuous operation to the stable state of the device, such as passivated metal oxide nanoparticles of which the surface is sufficiently modified.

In the optoelectronic devices of the above embodiments of the present application, the hole transport materials are respectively at least one selected from polymers containing aniline groups and copolymers containing fluorene groups and aniline groups, and these hole transport materials have the advantages of high hole transport efficiency, good stability, and easy access. In practical applications, the hole transport materials with a suitable energy level and mobility can be selected according to the actual application requirements, specifically:

In some specific embodiments, when a hole transport material with an absolute value of the top energy level of the valence band less than or equal to 5.3 eV is required in the optoelectronic device, the hole transport material with an absolute value of the top energy level of the valence band less than or equal to 5.3 eV can be chosen from: at least one of P09 and P13, the structural formula of P13 is:

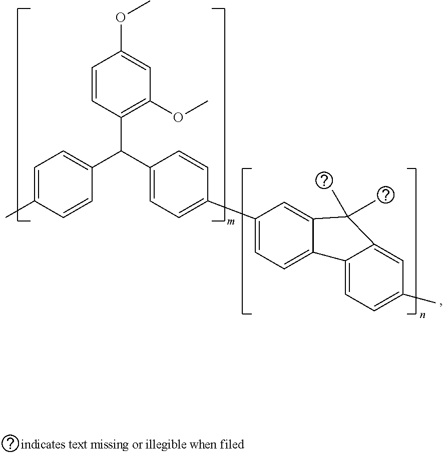

and the structural formula of P09 is:

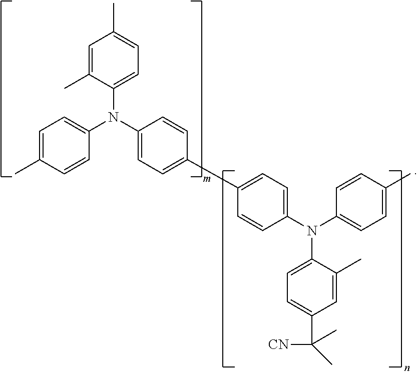

In some other specific embodiments, when a hole transport material with an absolute value of the top energy level of the valence band greater than 5.3 eV and less than 5.8 eV is required in the optoelectronic device, the hole transport material with an absolute value of the top energy level of the valence band greater than 5.3 eV and less than 5.8 eV includes at least one of: TFB, poly-TPD, and P11. The structural formula of P11 is:

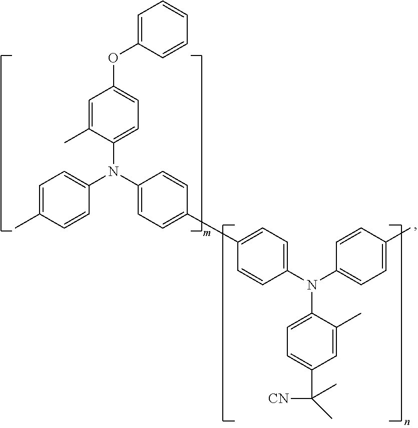

the structural formula of poly-TPD is:

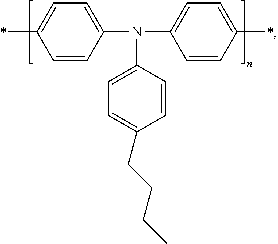

and the structural formula of TFB is:

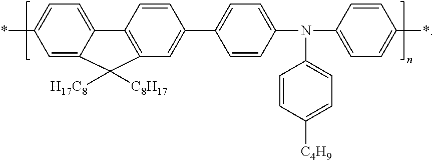

In some other specific embodiments, when a hole transport material with an absolute value of the top energy level of the valence band greater than or equal to 5.8 eV is required in the optoelectronic device, the hole transport material with an absolute value of the top energy level of the valence band greater than or equal to 5.8 eV includes at least one of P15 and P12. The structural formula of P12 is:

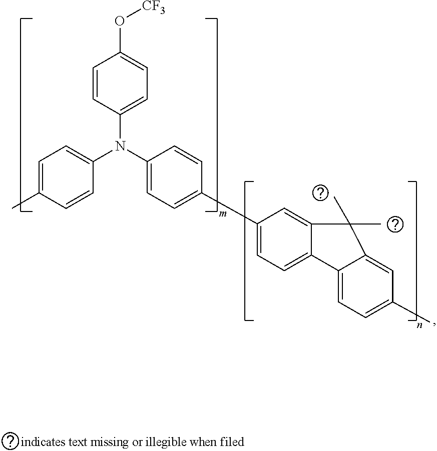

and the structural formula of P15 is:

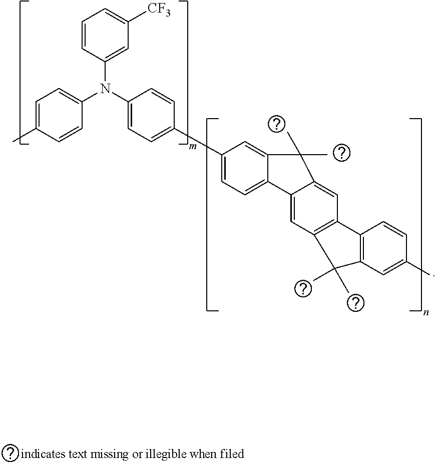

In some embodiments, the mobility of the hole transport material is higher than 1×10⁴ cm²/Vs. The high mobility ensures the hole transport migration and reduces the impact of charge accumulation on the device's lifetime.

In the above-mentioned embodiments of the present application, the quantum dot material of the core-shell structure includes the above-mentioned outer shell layer, and also includes a core, and an intermediate shell layer located between the core and the outer shell layer; the energy level of the top of the valence band of the core material is shallower than that of the outer shell layer material, and the energy level of the top of the valence band of the intermediate shell layer material is between that of the core material and that of the outer shell layer material. In the quantum dot material with a core-shell structure in the embodiment of the present application, the core material affects the luminescence performance, the outer shell material plays a role in protecting the luminous stability of the core and facilitating carrier injection, and the intermediate shell layer, which has a top energy level of the valence band between those of the core and the outer shell layer, plays the role of intermediate transition, which is conducive to carrier injection. The intermediate shell layer can form a stepped energy level transition from the core to the outer shell layer, which helps to achieve effective carrier injection, effective confinement and reduced scintillation at the lattice interface.

In some embodiments, the outer shell layer of the quantum dot material includes at least one of or an alloy material formed by at least two of CdS, ZnSe, ZnTe, ZnS, ZnSeS, CdZnS, and PbS. These shell layer materials not only protect the core luminescence stability and facilitate carrier injection into the quantum dot core for luminescence, but also form ΔE_{EML-HTL} energy level barriers greater than or equal to 0.5 eV with the HTL layer material, which can balance the hole and electron injection balance in the luminescence layer by increasing the hole injection barrier and reducing the hole injection efficiency, thus improving the device luminescence efficiency and reducing the charge accumulation on the device lifetime.

In some embodiments, the core of quantum dot material includes at least one of: CdSe, CdZnSe, CdZnS, CdSeS, CdZnSeS, InP, InGaP, GaN, GaP, ZnSe, ZnTe, and ZnTeSe. The luminescence performance of the quantum dot material is related to the core material, which ensures that QLED devices achieve luminescence in visible light ranging from 400 nm to 700 nm, not only meeting the required range for optoelectronic display device applications, but also enabling better representation of the advantageous effects achieved by the interrelationship of the energy levels of these materials.

In some embodiments, the intermediate shell layer material is at least one selected from CdZnSe, ZnSe, CdZnS, CdZnSeS, CdS, and CdSeS. In a specific embodiment of the present application, the intermediate shell layer is selected to form a continuous natural transition in terms of the compositions from the core to the outer shell layer, which helps to achieve the least lattice mismatch and the least lattice defects among the core, the intermediate shell layer, and the outer shell layer, thus realizing the optimal luminescence performance of the core-shell quantum dot material.

In some embodiments, the wavelength range of the light-emitting peak of the quantum dot material is 400-700 nm, on the one hand, this wavelength range is the range required for the application of optoelectronic display devices, on the other hand, the light-emitting layer of the device within this wavelength range can achieve a better representation of the advantageous effects realized by the interrelationship of the energy levels.

In some embodiments, the thickness of the outer shell layer of the quantum dot material is 0.2-6.0 nm, which covers the thickness of the conventional shell layers and can be widely applicable in QLED devices of different systems. If the thickness of the outer shell layer is too large, the rate of carrier injection into the luminescent quantum dots through the tunneling effect will be reduced; while the thickness of the outer shell layer is too small, the outer shell material cannot provide sufficient protective effect and passivation effect on the core material, which affects the luminescent performance and stability performance of the quantum dot material.

In the above embodiments of the present application, the optoelectronic device further includes an electron transport layer, and the electron transport material in the electron transport layer is at least one selected from a metal-chalcogenide transport material and an organic transport material. The metal-chalcogenide transport material generally has a high electron mobility and can be prepared as a thin film in the QLED device by solution method or by vacuum sputtering. The organic electron transport layer material can realize modulation in a wide range of energy levels and can be prepared as a thin film in QLED devices by vacuum vapor deposition or solution method; where the solution method includes ink-jet printing, spin coating, spray printing, slit coating, or screen printing, etc. A more suitable electron transport material may be flexibly selected according to the actual application requirements.

In some embodiments, the metal-chalcogenide transport material is at least one selected from zinc oxide, titanium oxide, zinc sulfide, and cadmium sulfide. All of these metal oxide transport materials adopted in the above embodiments of the present application have high electron migration efficiency. In some embodiments, to improve the electron migration efficiency, the metal-chalcogenide transport material is at least one selected from zinc oxide, titanium oxide, zinc sulfide, and cadmium sulfide that is doped with a metal element, the metal element includes at least one of aluminum, magnesium, lithium, lanthanum, yttrium, manganese, gallium, iron, chromium, and cobalt, which can improve the electron migration efficiency of the material.

In some embodiments, the particle size of metal-chalcogenide transport material is less than or equal to 10 nm. On the one hand, the metal oxide transport with a small particle size is more conducive to depositing an electron transport layer film with a dense film and a uniform thickness, which improves the bonding tightness with adjacent functional layers, reduces the interface resistance, and is more conducive to improving the device performance. On the other hand, the wider band gap of the metal-chalcogenide transport material with a small particle size has a wider band gap, which reduces the quenching of the exciton luminescence of the quantum dot material and improves the device efficiency.

In some embodiments, the electron mobility of the metal-chalcogenide transport material is 10⁻²-10⁻³ cm²/Vs, and the electron transport material with high mobility can reduce the accumulation of charges in the interface layer and improve the efficiency of electron injection and recombination

In some embodiments, the organic transport material has an electron mobility of no less than 10⁻⁴ cm²/Vs. In some embodiments, the organic transport material is at least one selected from 8-hydroxyquinoline-lithium (Alq₃), 8-hydroxyquinoline aluminum, fullerene derivative PCBM, 3,5-bis(4-tert-butylphenyl)-4-phenyl-4H-1,2,4-triazole (BPT), 1,3,5-tris(1-phenyl-1H-benzimidazol-2-yl)benzene (TPBi). These organic transport materials can achieve the modulation of energy levels in a wide range, which is more conducive to the modulation of the energy levels of each functional layer of the device and improve the stability and optoelectronic conversion efficiency of the device.

In some embodiments, the electron transport layer has a laminated composite structure, which includes at least two sub-electron transport layers. By selecting sub-electron transport layers with different transport migration efficiency and energy level regulation characteristics, the properties of the electron transport layer can be more flexibly regulated, thus optimizing device performance.

In some embodiments, the material of at least one sub-electron transport layer in the electron transport layer is a metal-chalcogenide transport material. In some embodiments, in the electron transport layer, all of the sub-electron transport layers are metal oxides, and the metal-chalcogenide transport materials for the different sub-electron transport layers may be the same or different. That is, the multilayer electron transport layer in which all sub-electron transport layers are metal oxides may include at least one layer of sub-electron transport layer of metal oxide nanoparticles and at least one layer of sub-electron transport layer of non-nanoparticle-type metal oxide. It may also have sub-electron transport layers of doped and intrinsic metal oxides, respectively (e.g., Mg-doped ZnO+intrinsic ZnO). It may also have sub-electron transport layers of the same metal oxide nanoparticles. When the sub-electron transport layers are all the same metal oxide nanoparticles, the electron mobility of the different sub-electron transport layers may be the same or different.

In some embodiments, the material of at least one sub-electron transport layer in the electron transport layer is an organic transport material. In some embodiments, the material of at least one sub-electron transport layer in the electron transport layer is a metal-chalcogenide transport material, and the material of at least one sub-electron transport layer thereof is an organic transport material, and the metal-chalcogenide transport materials of different sub-electron transport layers may be the same or different; the metal-chalcogenide transport material is selected to be nanoparticles of the corresponding metal oxide. Through the joint modulation of the metal-chalcogenide transport material and the organic transport material in the electron transport layer, the electron transport layer has both high electron mobility and the flexibility of energy level modulation. The energy level and electron mobility of the electron transport layer are effectively modulated so as to achieve sufficient matching with the hole injection. In some specific embodiments, the electron transport layer including a plurality of sub-electron transport layers may be a laminated composite structure such as a combination of ZnO nanoparticles+NaF, a combination of Mg-doped ZnO nanoparticles+NaF, and the like.

As in the core-shell structure of quantum dot material, the core material affects the luminescence performance of quantum dot material, and the shell layer material provides a protective effect as well as facilitates carrier injection. When the shell layer material is determined, the expected injection barrier, E_{EML-HTL}≥0.5 eV, can be constructed by adjusting the thickness of the shell layer and the size of the energy level of the top of the valence band of the hole transport material, etc., so that the energy level difference between the top of the valence bands of the shell layer material of the quantum dot material and the hole transport material is greater than or equal to 0.5 eV, thereby optimizing the balance of electron-and hole-injection efficiency in the light-emitting layer and improve the device efficiency and lifetime.

As shown in the accompanying FIG. 6, a sixth aspect of the present application provides an optoelectronic device including a quantum dot light-emitting layer and a hole transport layer, the quantum dot light-emitting layer includes a quantum dot material with a core-shell structure, the outer shell layer of the quantum dot material is ZnSe, and the absolute value of the energy level of the top of the valence band of the hole transport material in the hole transport layer is less than or equal to 5.4 eV.

On the premise that the outer shell layer of the quantum dot material is specifically ZnSe, the optoelectronic device provided in the sixth aspect of the present application is designed to be structured according to the energy level and other properties of ZnSe. Specifically, due to the relatively shallow valence band energy level (small absolute value of the energy level) of the ZnSe outer shell material, if a hole injection barrier with a top energy level difference (ΔE_{EML-HTL}) between the valence bands greater than or equal to 0.5 eV is to be constructed, the absolute value of the energy level of the top of the valence band of the hole transport material should be less than or equal to 5.4 eV. Such that ΔE_{EML-HTL}≥0.5 eV, which constructs a hole injection barrier, reduces the hole injection rate, balances the injection efficiency of electrons and holes in the light-emitting layer, reduces carrier accumulation, and improves the luminescence efficiency.

In some embodiments, in the quantum dot material, the thickness of the ZnSe shell layer is 2-5 nm. In the embodiment of the present application, since the bandgap of ZnSe is relatively narrow, the ability to bind excitons in the quantum dot core is relatively poor. In order to ensure the good luminescence efficiency of the quantum dot core luminescent material itself, a thicker ZnSe shell thickness is required. The selected thickness of the shell layer is 2.0-5.0 nm. If the thickness of the shell layer is too large, the rate of carriers injected into the luminescent quantum dots through the tunneling effect will be reduced; while the thickness of the shell layer is too small, the rate of carriers injected into the luminescent quantum dots through the tunneling effect will be reduced. However, when the thickness of the outer shell layer is too small to a certain extent, the outer shell layer structure will not be able to protect and passivate the core sufficiently, thereby affecting the luminescent performance and stability of the quantum dot material.

In some embodiments, the peak wavelength of the quantum dot material is 510-640 nm. For the blue core-shell quantum dots with a short wavelength and a wide band gap, even with a thick ZnSe outer shell layer, it is still not possible to fully guarantee the luminescence efficiency of the quantum dot material itself. Therefore, the quantum dot light-emitting material selected in the embodiment of the present application should be red or green quantum dots with a luminescence peak wavelength range of 510-640 nm, so as to better ensure the luminous efficiency of the quantum dots.

In some embodiments, the energy level difference between the ZnSe material and the hole transport material is 0.5-1.0 eV. In the embodiment of the present application, due to the relatively thick ZnSe outer shell layer, the rate at which carriers are injected into the luminescent quantum dots through the tunneling effect becomes weaker, so difference between the energy level of the top of the valence band (ΔE_{EML-HTL}) Of the corresponding hole transport layer material and the quantum dot outer shell material may be selected between 0.5-1.0 eV. If ΔE_{EML-HTL} is too large, the efficiency of hole injection into the quantum dot light-emitting core will be reduced, which will affect the luminous efficiency of the quantum dot material.

In some embodiments, the absolute value of the top energy level of the valence band of the hole transport material is 4.9 eV-5.4 eV, in which range a more suitable hole injection barrier can be constructed with the ZnSe outer shell material to optimize the carrier injection and recombination efficiency in the light-emitting layer.

In some specific embodiments, the absolute value of the top energy level of the valence band of the hole transport material is 4.9 eV-5.4 eV, here, the difference between the energy level of the top of the valence band of the ZnSe material and the hole transport material is 0.5-1.0 eV.

In some embodiments, the mobility of the hole transport material is higher than 1×10⁻³ cm²/Vs. Since the absolute value of the energy level of the top of the valence band of the hole transport material used in the present application is less than or equal to 5.4 eV, the energy level is shallow, and the hole transport layer material with a shallow top energy level of the valence band usually has higher hole mobility, which is beneficial to the effective hole transport in the hole transport layer film of certain thickness. This reduces the overall resistance of the device, thus reducing the device drive voltage and improving the device lifetime.

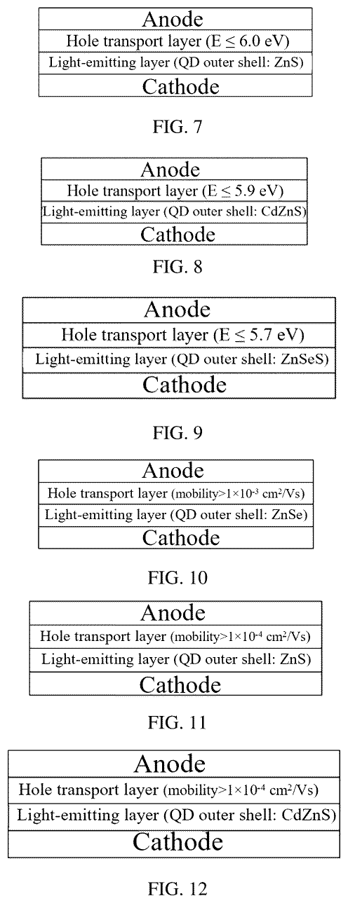

As shown in FIG. 7, a seventh aspect of the present application provides an optoelectronic device including a quantum dot light-emitting layer and a hole transport layer, the quantum dot light-emitting layer includes a quantum dot material with a core-shell structure, the outer shell layer of the quantum dot material is ZnS, and the absolute value of the energy level of the top of the valence band of the hole transport material in the hole transport layer is less than or equal to 6.0 eV.

In the optoelectronic device provided in the seventh aspect of the present application, the structure of the optoelectronic device is designed on the premise that the outer shell layer of the quantum dot material is specifically ZnS, and according to the energy level and other characteristics of ZnS. Specifically, the valence band energy level of the ZnS shell material is deeper (the absolute value of the energy level is larger compared to that of ZnSe), and to construct a top energy level difference between the valence bands (ΔE_{EML-HTL}) greater than or equal to 0.5 eV, the energy level of the top of the valence band of the hole transport material should be less than or equal to 6.0 eV. Such that ΔE_{EML-HTL}≥0.5 eV, and the hole injection barrier is constructed, thereby reducing the hole injection rate, balancing the injection efficiency of electrons and holes in the light-emitting layer, reducing carrier accumulation and improving luminescence efficiency.

In some embodiments, the thickness of the ZnS shell layer is 0.2-2.0 nm. In the embodiment of the present application, due to the wide band gap of ZnS, the binding ability for the excitons in the quantum dot core is strong, so the use of a smaller ZnS outer shell layer thickness can basically ensure the good luminous efficiency of the quantum dot luminescent material, and the thickness of the shell layer is 0.2-2.0 nm. At the same time, the thin ZnS outer shell can also effectively reduce the overall resistance of the device, reduce the driving voltage of the device and improve the performance of the device.

In some embodiments, the absolute value of the energy level of the top of the valence band of the hole transport material is 4.9 eV-6.0 eV, in which range a more suitable hole injection barrier can be constructed with the ZnS shell material to optimize the carrier injection and recombination efficiency in the light-emitting layer. In some embodiments, the absolute value of the energy level of the top of the valence band of the hole transport material is 4.9 eV-5.5 eV.

In some embodiments, the energy level difference between the top of the valence bands of the ZnS material and the hole transport material is 1.0-1.6 eV. In the embodiment of the present application, the small thickness of the ZnS shell layer leads to a higher rate of carrier injection into the luminescent quantum dots through the tunneling effect, and therefore the energy level difference between the top of the valence bands of the corresponding hole transport layer material and the quantum dot outer shell layer material in the quantum dot light-emitting layer (ΔE_{EMLHTL}) needs to be increased appropriately to better balance the injection of holes and electrons, which should be in the range of 1.0-1.6 eV. If ΔE_{EML-HTL} is too large, the efficiency of hole injection into the quantum dot luminescent core will be reduced and the luminescence efficiency of the quantum dot material is affected.

In some embodiments, the peak wavelength of the quantum dot material is 400-700 nm. The present application is suitable for all quantum dot materials in the visible light region with a peak wavelength of 400-700 nm due to the wide band gap of ZnS and the strong binding ability of excitons in the core of the quantum dot, which can effectively ensure the luminous efficiency of the quantum dot material.

In some embodiments, the hole mobility is relatively low due to the deeper top energy level of the valence band (less than or equal to 6.0 eV) of the hole transport material employed in the embodiments of the present application, and the mobility of the hole transport material is higher than 1×10⁻⁴ cm²/Vs. In some embodiments, the mobility of the hole transport material is higher than 1×10⁻³ cm²/Vs.

As shown in FIG. 8, the eighth aspect of the embodiment of the present application provides an optoelectronic device, including a quantum dot light-emitting layer and a hole transport layer, the quantum dot light-emitting layer includes a quantum dot material with a core-shell structure, and an outer shell layer of the quantum dot material is CdZnS, and an absolute value of the energy level of the top of the valence band of the hole transport material in the hole transport layer is less than or equal to 5.9 eV.

In the optoelectronic device provided in the eighth aspect of the present application, the structure of the optoelectronic device is designed on the premise that the outer shell layer of the quantum dot material is specifically CdZnS, and according to the characteristics such as the energy level of CdZnS. Specifically, since the outer shell layer of the quantum dots in this embodiment uses CdZnS, the valence band energy level of which is between ZnSe and ZnS, and in order to construct a hole injection barrier with a top energy level difference of valence band (ΔE_{EML-HTL}) greater than or equal to 0.5 eV, the top energy level of the valence band of the hole transport material needs to be less than or equal to 5.9 eV. Through the hole injection barrier constructed, the hole injection rate is reduced, the injection efficiency of electrons and holes in the light-emitting layer is balanced, the accumulation of carriers is reduced, and the luminous efficiency is improved.

In some embodiments, the thickness of the CdZnS shell layer is 0.5-3.0 nm. Since the band gap of CdZnS is between ZnSe and ZnS, when the thickness of the outer shell layer is 0.5-3.0 nm, both the ability to bind the excitons in the core of the quantum dot and the good luminous efficiency of the quantum dot luminescent material can be guaranteed.

In some embodiments, the absolute value of the top energy level of the valence band of the hole transport material is 4.9-5.9 eV, and within this range, a more suitable hole injection barrier can be constructed with the CdZnS shell material, and the carrier injection and recombination efficiency in the light-emitting layer can be optimized. In some embodiments, the absolute value of the energy level of the top of the valence band of the hole transport material is 4.9-5.5 eV.

In some embodiments, the energy level difference between the CdZnS material and the hole transport material is 0.8-1.4 eV. In the embodiment of the present application, the range of the top energy level difference (ΔE_{EML-HTL}) between the valence bands of the hole transport layer material and the quantum dot shell layer material in the quantum dot light-emitting layer is 0.8-1.4 eV, which can ensure the injection of carriers into the luminescent quantum dot core through the tunneling effect, as well as balance the injection efficiency of holes and electrons. If the ΔE_{EML-HTL} is too large, the efficiency of carrier injection into the luminescent quantum dot core through the tunneling effect is reduced; if the ΔE_{EML-HTL} is too small, the injection rate of holes is poorly regulated.

In some embodiments, the luminescence peak wavelength of the quantum dot material is 400-700 nm. In the embodiment of the present application, because CdZnS has a relatively strong binding ability to the excitons in the quantum dot core, it can effectively ensure the luminous efficiency of the quantum dot material, and is suitable for all quantum dot materials with a luminous peak wavelength of 400-700 nm in the range of the visible light, thus having a wide range of applications.

In some embodiments, due to the deep energy level of the top of the valence band (less than or equal to 5.9 eV) of the hole transport material used in the embodiment of the present application, the hole mobility is relatively low, and the mobility of the hole transport material is higher than 1×10⁻⁴ cm²/Vs. In some embodiments, the mobility of the hole transport material is higher than 1×10⁻³ cm²/Vs.

As shown in FIG. 9, the ninth aspect of the embodiment of the present application provides an optoelectronic device, including a quantum dot light-emitting layer and a hole transport layer, the quantum dot light-emitting layer contains a quantum dot material with a core-shell structure, and an outer shell layer of the quantum dot material is ZnSeS, and an absolute value of the top energy level of the valence band of the hole transport material in the hole transport layer is less than or equal to 5.7 eV.

In the optoelectronic device provided in the ninth aspect of the present application, the structure of the optoelectronic device is designed on the premise that the outer shell layer of the quantum dot material is specifically ZnSeS, and according to the energy level and other characteristics of ZnSeS. Specifically, since the outer shell layer of the quantum dots in this embodiment uses ZnSeS, the valence band energy level of which is between ZnSe and ZnS, and in order to construct a hole injection potential barrier with a top energy level difference of valence band (ΔE_{EML-HTL}) greater than or equal to 0.5 eV, the top energy level of the valence band of the hole transport material needs to be less than or equal to 5.7 eV. Through the hole injection barrier constructed, the hole injection rate is reduced, the injection efficiency of electrons and holes in the light-emitting layer is balanced, the accumulation of carriers is reduced, and the luminous efficiency is improved.

In some embodiments, the thickness of the ZnSeS shell is 1.0-4.0 nm. Since the easily oxidized Se in the ZnSeS outer shell is closer to the surface of the quantum dots, the ZnSeS outer shell needs to be thicker to ensure sufficient protection and passivation for the core, so that the thickness of the ZnSeS outer shell layer is 1.0-4.0 nm.

In some embodiments, the absolute value of the top energy level of the valence band of the hole transport material is 4.9-5.7 eV, and within this range, a more suitable hole injection barrier can be constructed with the ZnSeS outer shell material to optimize the carrier injection and recombination efficiency in the light-emitting layer. In some embodiments, the absolute value of the energy level of the top of the valence band of the hole transport material is 4.9-5.4 eV.

In some embodiments, the energy level difference between the ZnSeS material and the hole transport material is 0.9-1.4 eV. In the embodiment of the present application, when the top energy level difference (ΔE_{EML-HTL}) between the valence bands of the hole transport layer material and the quantum dot shell layer material in the quantum dot light-emitting layer is 0.9-1.4 eV, the efficiency of carrier injection into the luminescent quantum dot through the tunneling effect can be ensured and the injection efficiency of holes and electrons can be better balanced. If the ΔE_{EML-HTL} is too large, the efficiency of carrier injection into the luminescent quantum dot core through the tunneling effect is reduced; if the ΔE_{EML-HTL} is too small, the injection rate of holes is poorly regulated.

In some embodiments, the luminescence peak wavelength of the quantum dot material is 400-700 nm. In the embodiment of the present application, because ZnSeS has a relatively strong binding ability to the excitons in the quantum dot core, it can effectively ensure the luminous efficiency of the quantum dot material itself, and is suitable for all quantum dot materials with a luminous peak wavelength of 400-700 nm in the range of the visible light, thus having a wide range of applications.

In some embodiments, since the hole transport material used in the embodiments of the present application has a deeper top energy level of the valence band (less than or equal to 5.7 eV), the hole mobility is relatively low, and the mobility of the hole transport material is higher than 1×10⁻⁴ cm²/Vs. In some embodiments, the mobility of the hole transport material is higher than 1×10⁻³ cm²/Vs.

In the optoelectronic devices provided in the sixth to ninth aspects of the present application, the hole transport material is at least one selected from a polymer containing an aniline group and a copolymer containing a fluorene group and an aniline group. In practical applications, a hole transport material with a suitable mobility may be selected according to specific application requirements.

In some embodiments, the polymer containing an aniline group of the hole transport material with an absolute value of the energy level of the top of the valence band less than or equal to 5.4 eV includes poly-TPD, P9, TFB, and P13.

In some embodiments, the copolymer containing a fluorene group and an aniline group of the hole transport material with an absolute value of the energy level of the top of the valence band less than or equal to 5.4 eV includes: TFB and P13.

In some embodiments, the polymer containing an aniline group of the hole transport material with an absolute value of the energy level of the top of the valence band greater than 5.4 eV and less than or equal to 5.9 eV includes: P11, P12, and P15.

In some embodiments, the copolymer containing a fluorene group and an aniline group of the hole transport material with an absolute value of the energy level of the top of the valence band greater than 5.4 eV and less than or equal to 5.9 eV includes: P12 and P15.

In the optoelectronic devices provided in the sixth to ninth aspects of the present application, the quantum dot material of the core-shell structure includes the above-mentioned outer shell layer, and also includes a core and an intermediate shell layer between the core and the outer shell layer; the top energy level of the valence band of the core material is shallower than that of the outer shell material; the top energy level of the valence band of the intermediate shell material is between that of the core material and that of the outer shell material.

In some embodiments, the core material is at least one selected from semiconductor compounds of Groups II-IV, II-VI, II-V, III-V, III-VI, IV-VI, I-III-VI, II-IV-VI, and II-IV-V. In some specific embodiments, the core material is at least one selected from CdSe, CdZnSe, CdSeS, CdZnSeS, InP, InGaP, GaP, ZnTe, and ZnTeSe. These core materials have good luminescence properties, and have a good coordination effect with the outer shell layer of ZnSe, ZnS, CdZnS, or ZnSeS.

In some specific embodiments, the intermediate shell material is at least one selected from CdZnSe, ZnSe, CdZnS, CdZnSeS, CdS, and CdSeS. The selection principle of the intermediate shell in the embodiment of the present application is: the composition of the intermediate shell should preferably form a continuous and natural transition from the core to the outer layer, which helps to realize the least lattice mismatch and the least lattice defects between the core, the intermediate shell, and the outer shell, so as to achieve the optimal luminescence performance of the core-shell quantum dot material itself, the intermediate shell generally needs to form a stepped energy-level transition from the core to the shell, which helps to achieve effective carrier injection, effective binding, and reduced lattice interface scintillation.

In the optoelectronic devices provided in the sixth to ninth aspects of the present application, the optimization of the hole injection functional layer in the optoelectronic devices of the second or third aspects may also be combined, and may include a first hole injection layer. An absolute value of the difference between the work function of a first hole injection material of the first hole injection layer and the energy level of the top of the valence band of the hole transport material is less than or equal to 0.2 eV. Alternatively, a second hole injection layer may be included, and a difference between the energy level of the top of the valence band of the hole transport layer and the work function of a second hole injection material in the second hole injection layer is less than −0.2 eV. This improves the hole utilization rate in the device, finely regulates the hole injection rate, balances the carrier injection in the device, and improves the recombination efficiency; at the same time, reduces the impact of charge accumulation in the interface layer on the device life.

In the optoelectronic devices provided in the sixth to ninth aspects of the present application, an electron transport layer may also be included, and the electron transport layer includes at least two sub-electron transport layers stacked with each other; the material of at least one sub-electron transport layer is a metal-chalcogenide transport material. Alternatively, the material of at least one sub-electron transport layer is an organic transport material. Alternatively, at least one sub-electron transport layer of a metal-chalcogenide transport material and one sub-electron transport layer material of an organic transport material are included.

As shown in FIG. 10, the tenth aspect of the embodiment of the present application provides an optoelectronic device, including a quantum dot light-emitting layer and a hole transport layer, the quantum dot light-emitting layer includes a quantum dot material with a core-shell structure, and an outer shell layer of the quantum dot material is ZnSe, and the mobility of the hole transport material in the hole transport layer is higher than 1×10⁻³ cm²/Vs.

In the optoelectronic device provided by the tenth aspect of the present application, since the valence band energy level of the ZnSe outer shell material is relatively shallow (the absolute value of the energy level is small), the band gap is relatively narrow, and the binding ability for the excitons in the quantum dot of the core-shell structure is relatively poor, in order to ensure a good luminous efficiency of the quantum dot luminescent material itself, it is necessary to use a thicker ZnSe outer shell, so that the injection rate into the luminescent quantum dots through the tunneling effect becomes weaker. In the quantum dot layer with the outer shell layer of ZnSe, in order to satisfy the structure in which the hole injection barrier between the quantum dot outer shell layer in the HTL and the quantum dot outer shell layer in the EML, E_{EML-HTL}≥0.5 eV, an HTL material with high hole mobility, with mobility higher than 1×10⁻³ cm²/Vs, is required, to make up for the influence of tunneling effect on the hole injection rate, balance the injection efficiency of electrons and holes in the light-emitting layer, reduce carrier accumulation, and improve luminous efficiency.

In some embodiments, in the quantum dot material, the thickness of the ZnSe outer shell is 2-5 nm. In the embodiment of the present application, since the bandgap of ZnSe is relatively narrow, the ability to bind excitons in the quantum dot core is relatively poor. In order to ensure the good luminous efficiency of the quantum dot core luminescent material itself, a thicker ZnSe outer shell is required, the thickness of the outer shell layer being 2.0-5.0 nm. If the thickness of the outer shell layer is too large, the injection rate of carriers into the luminescent quantum dots through the tunneling effect will be reduced; while the thickness of the outer shell layer is too small, the injection rate of carriers into the luminescent quantum dots through the tunneling effect will be enhanced. However, when the thickness of the outer shell layer is too small, the structure of the outer shell layer cannot sufficiently protect and passivate the core, thereby affecting the luminescence performance and stability of the quantum dot material.

In some embodiments, the luminescence peak wavelength of the quantum dot material is 510-640 nm. For the blue core-shell quantum dots with shorter emission wavelength and wider band gap of the quantum dot core, even if a thick ZnSe outer shell layer is used, the luminous efficiency of the quantum dot material itself cannot be fully guaranteed. The quantum dot luminescent material in the embodiment of the present application should be red or green quantum dots with a luminescence peak wavelength range of 510-640 nm, so as to better ensure the luminous efficiency of the quantum dots.

In some embodiments, the energy level difference between the ZnSe material and the hole transport material is 0.5-1.0 eV. In the embodiment of the present application, due to the thicker ZnSe outer shell layer, the injection rate of the carriers into the luminescent quantum dots through the tunneling effect becomes weaker, so the top energy level difference between the valence bands (ΔE_{EML-HTL}) between the corresponding hole transport layer material and the quantum dot outer shell material should not be too large, and the range thereof should be between 0.5 eV and 1.0 eV. If the ΔE_{EML-HTL} is too large, the injection efficiency of holes into the quantum dot light-emitting core will be reduced, which will affect the luminous efficiency of the quantum dot material.

In some embodiments, the absolute value of the energy level of the top of the valence band of the hole transport material is 4.9 eV-5.4 eV, and within this range, a more suitable hole injection barrier can be constructed with the ZnSe outer shell material, and the carriers injection and recombination efficiency in the light-emitting layer can be optimized.

As shown in FIG. 11, the eleventh aspect of the embodiment of the present application provides an optoelectronic device, including a quantum dot light-emitting layer and a hole transport layer, the quantum dot light-emitting layer contains a quantum dot material with a core-shell structure, and an outer shell layer of the quantum dot material is ZnS, and the mobility of the hole transport material in the hole transport layer is higher than 1×10⁻⁴ cm²/Vs.

In the optoelectronic device provided by the eleventh aspect of the present application, when ZnS is used as the quantum dot outer shell material, since ZnS has a wider band gap, thus a stronger binding ability for the excitons in the quantum dot core-shell structure, and a thinner ZnS outer shell layer is used to generally guarantee the good luminous efficiency of the quantum dot luminescent material itself, so that the injection rate of carriers into the luminescent quantum dot through the tunneling effect becomes stronger. The hole mobility of the hole transport material used is greater than or equal to 1×10⁻⁴ cm²/Vs, which can realize a hole injection barrier that a difference between the energy levels of the top of the valence band of the outer shell material of the quantum dot material and the hole transport material is greater than or equal to 0.5 eV, namely E_{EML-HTL}≥0.5 eV, and ensure the efficiency of hole transport and injection into the quantum dot material.

In some embodiments, the thickness of the ZnS outer shell layer is 0.2-2.0 nm. In the embodiment of the present application, due to the wide band gap of ZnS, the binding ability for the excitons in the quantum dot core is strong, so the use of a thinner ZnS shell layer can basically ensure the good luminous efficiency of the quantum dot luminescent material itself, with the thickness of the outer shell layer being 0.2-2.0 nm. At the same time, the thin ZnS outer shell can also effectively reduce the overall resistance of the device, reduce the driving voltage of the device and improve the performance of the device.

In some embodiments, the absolute value of the top energy level of the valence band of the hole transport material is 4.9 eV-6.0 eV, and within this range, a more suitable hole injection barrier can be constructed with the ZnS outer shell material, and the carrier injection and recombination efficiency in the light-emitting layer can be optimized. In some embodiments, the absolute value of the top energy level of the valence band of the hole transport material is 4.9 eV-5.5 eV.

In some embodiments, the difference between the top energy levels of the valence band of the ZnS material and the hole transport material is 1.0 eV-1.6 eV. In the embodiment of the present application, since the ZnS outer shell layer has a smaller thickness, the injection rate of the carriers into the luminescent quantum dots through the tunneling effect becomes stronger, so the top energy level difference between the valence bands (ΔE_{EML-HTL}) of the corresponding hole transport layer material and the quantum dot outer shell layer in the quantum dot light-emitting layer needs to be appropriately increased to better balance the injection of holes and electrons, and the range thereof should be between 1.0 eV and 1.6 eV. If ΔE_{EML-HTL} is too large, the injection efficiency of holes into the quantum dot light-emitting core will be reduced, which will affect the luminous efficiency of the quantum dot material.

In some embodiments, the luminescence peak wavelength of the quantum dot material is 400-700 nm. In the embodiment of the present application, due to the wide band gap of ZnS, it has a strong binding ability for the excitons in the quantum dot core, which can effectively ensure the luminous efficiency of the quantum dot material itself, and is suitable for all quantum dot materials with a luminous peak wavelength of 400-700 nm in the visible light region, thereby having a wide range of applications.

In some embodiments, the mobility of the hole transport material is higher than 1×10⁻³ cm²/Vs.

As shown in FIG. 12, the twelfth aspect of the embodiment of the present application provides an optoelectronic device, including a quantum dot light-emitting layer and a hole transport layer, the quantum dot light-emitting layer contains a quantum dot material with a core-shell structure, and an outer shell layer of the quantum dot material is CdZnS, and the mobility of the hole transport material in the hole transport layer is higher than 1×10⁻⁴ cm²/Vs.

In the optoelectronic device provided in the twelfth aspect of the present application, the shell layer of the quantum dots is made of CdZnS, the bandgap width of which is between that of ZnSe and ZnS, and its ability to bind excitons in the core-shell structure of the quantum dots is moderate, so that a relatively moderate thickness of the CdZnS outer shell layer can basically guarantee a good luminous efficiency of the quantum dot luminescent material, so the thickness of the outer shell layer has little influence on the tunneling effect of the carriers. At the same time, the valence band energy level of the CdZnS outer shell material is between that of ZnSe and ZnS. To construct a hole injection barrier with a top energy level difference between the valence bands (ΔE_{EML-HTL}) greater than or equal to 0.5 eV, the required energy level of the top of the valence band of the hole transport material is relatively shallow. Therefore, when the hole mobility of the HTL material is greater than or equal to 1×10⁻⁴ cm²/Vs, it can satisfy the construction of the hole injection barrier of ΔE_{EML-HTL}≥0.5 eV and in the meanwhile ensure the efficiency of the hole transport and injection into the quantum dot material.

In some embodiments, the thickness of the CdZnS outer shell layer is 0.5-3.0 nm. Since the band gap of CdZnS is between that of ZnSe and ZnS, when the thickness of the outer shell layer is 0.5-3.0 nm, the ability to bind the excitons in the core of the quantum dot and the good luminous efficiency of the quantum dot luminescent material can be guaranteed at the same time.

In some embodiments, the absolute value of the top energy level of the valence band of the hole transport material is 4.9-5.9 eV, and within this range, a more suitable hole injection barrier can be constructed with the CdZnS outer shell material, optimizing the carrier injection and recombination efficiency in the light-emitting layer. In some embodiments, the absolute value of the energy level of the top of the valence band of the hole transport material is 4.9-5.5 eV.

In some embodiments, the energy level difference between the top of the valence bands of the CdZnS material and the hole transport material is 0.8-1.4 eV. In the embodiment of the present application, the range of the top energy level difference between the valence bands (ΔE_{EML-HTL}) of the hole transport layer material and the quantum dot shell layer material in the quantum dot light-emitting layer is 0.8-1.4 eV, which can ensure the injection efficiency of carriers into the luminescent quantum dots through the tunneling effect, and better balance the injection efficiency of holes and electrons. If the ΔE_{EML-HTL} is too large, the efficiency of carrier injection into the luminescent quantum dot core through the tunneling effect is reduced; if the ΔE_{EML-HTL} is too small, the injection rate of holes is poorly regulated.

In some embodiments, the luminescence peak wavelength of the quantum dot material is 400-700 nm. In the embodiment of the present application, because CdZnS has a relatively strong binding ability to the excitons in the quantum dot core, it can effectively ensure the luminous efficiency of the quantum dot material itself, and is suitable for all quantum dot materials with a luminous peak wavelength of 400-700 nm in the visible light region, having a wide range of applications.

In some embodiments, the mobility of the hole transport material is higher than 1×10⁻³ cm²/Vs.

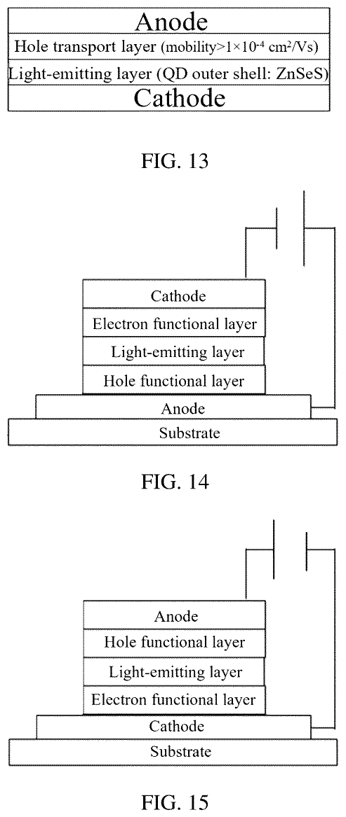

As shown in FIG. 13, the thirteenth aspect of the embodiment of the present application provides an optoelectronic device, including a quantum dot light-emitting layer and a hole transport layer, the quantum dot light-emitting layer contains a quantum dot material with a core-shell structure, and an outer shell layer of the quantum dot material is ZnSeS, and the mobility of the hole transport material in the hole transport layer is higher than 1×10⁻⁴ cm²/Vs.

In the optoelectronic device provided by the thirteenth aspect of the present application, the outer shell layer of the quantum dots is ZnSeS, which has a bandgap width between that of ZnSe and ZnS, and the binding ability for the excitons in the quantum dot core-shell structure is moderate, and the outer shell has little influence on the tunneling effect of carriers. At the same time, the valence band energy level of the ZnSeS shell material is between that of ZnSe and ZnS. To construct a hole injection barrier with a top energy level difference between the valence bands (ΔE_{EML-HTL}) greater than or equal to 0.5 eV, the required top energy level of the valence band of the hole transport material is relatively shallow. Therefore, when the hole mobility of the HTL material is greater than or equal to 1×10⁻⁴ cm²/Vs, it can satisfy the construction of the hole injection barrier and ensure the efficiency of hole transport and injection into the quantum dot material at the same time.

In some embodiments, the thickness of the ZnSeS shell layer is 1.0-4.0 nm. Since the easily oxidized Se in the ZnSeS shell is closer to the surface of the quantum dots, the ZnSeS shell layer needs to be thicker to ensure sufficient protection and passivation for the core, so that the thickness of the ZnSeS shell layer is 1.0-4.0 nm.

In some embodiments, the absolute value of the top energy level of the valence band of the hole transport material is 4.9-5.7 eV, and within this range, a more suitable hole injection barrier can be constructed with the ZnSeS outer shell material to optimize the carrier injection and recombination efficiency in the light-emitting layer. In some embodiments, the absolute value of the energy level of the top of the valence band of the hole transport material is 4.9-5.4 eV.

In some embodiments, the energy level difference between the top of the valence bands of the ZnSeS material and the hole transport material is 0.9-1.4 eV. In the embodiment of the present application, when the top energy level difference (ΔE_{EML-HTL}) between the valence bands of the material of the hole transport layer and the material of the quantum dot shell layer in the quantum dot light-emitting layer ranges from 0.9 eV to 1.4 eV, the injection efficiency of carriers into the luminescent quantum dots through the tunneling effect can be ensured, and the injection efficiency of holes and electrons can be well balanced. If the ΔE_{EML-HTL} is too large, the injection efficiency of carriers into the luminescent quantum dot core through the tunneling effect is reduced; if the ΔE_{EML-HTL} is too small, the injection rate of holes is poorly regulated.

In some embodiments, the luminescence peak wavelength of the quantum dot material is 400-700 nm. In the embodiment of the present application, because ZnSeS has a relatively strong binding ability to the excitons in the quantum dot core, it can effectively ensure the luminous efficiency of the quantum dot material itself, and is suitable for all quantum dot materials with a luminous peak wavelength of 400-700 nm in the visible light region, thereby having a wide range of applications.

In some embodiments, the mobility of the hole transport material is higher than 1×10⁻³ cm²/Vs.

In the optoelectronic devices provided in the tenth to thirteenth aspects of the present application, the hole transport material is at least one selected from a polymer containing an aniline group and a copolymer containing a fluorene group and an aniline group. In practical applications, according to the specific application requirements, the hole transport material with a suitable mobility may be selected.

In some embodiments, the polymer containing an aniline group of the hole transport material having a mobility higher than 1×10⁻³ cm²/Vs includes: poly-TPD, TFB, P9, P11, and P13.

In some embodiments, the containing a fluorene group and an aniline group of the hole transport material having a mobility higher than 1×10⁻³ cm²/Vs includes: TFB and P13.

In some embodiments, the polymer containing an aniline group of the hole transport material having a mobility higher than 1×10⁻⁴ cm²/Vs includes: poly-TPD, TFB, P9, P11, P13, and P15.

In some embodiments, the copolymer containing a fluorene group and an aniline group of the hole transport material having a mobility higher than 1×10⁻⁴ cm²/Vs includes: TFB, P13, and.

In the optoelectronic devices provided in the tenth to thirteenth aspects of the present application, the quantum dot material with core-shell structure also includes an core, and an intermediate shell layer between the core and the outer shell; the energy level of the top of the valence band of the core material is shallower than that of the outer shell material; the energy level of the top of the valence band of the intermediate shell material is between that of the core material and the outer shell material.

In some embodiments, the core material is at least one selected from semiconductor compounds of Groups II-IV, II-VI, II-V, III-V, III-VI, IV-VI, I-III-VI, II-IV-VI, and II-IV-V. In some specific embodiments, the core material is at least one selected from CdSe, CdZnSe, CdSeS, CdZnSeS, InP, InGaP, GaP, ZnTe, and ZnTeSe. These core materials have good luminescence properties, and have a good coordination effect with the outer shell layer of ZnSe, ZnS, CdZnS, or ZnSeS.

In some specific embodiments, the intermediate shell material is at least one selected from CdZnSe, ZnSe, CdZnS, CdZnSeS, CdS, and CdSeS. The selection principle of the intermediate shell in the embodiment of the present application is: the composition of the intermediate shell should preferably form a continuous and natural transition from the core to the outer layer, which helps to realize the least lattice mismatch and the least lattice defects between the core, the intermediate shell, and the outer shell, so as to achieve the optimal luminescence performance of the core-shell quantum dot material; the intermediate shell generally needs to form a stepped energy-level transition from the core to the shell, which helps to achieve effective carrier injection, effective binding, and reduced lattice interface scintillation.

In the optoelectronic devices provided in the tenth to thirteenth aspects of the present application, the optimization of the hole injection functional layer in the optoelectronic devices in the second or third aspects above can also be combined, so that a first hole injection layer is included, The absolute value of the difference between the work function of the first hole injection material of the first hole injection layer and the energy level of the top of the valence band of the hole transport material is less than or equal to 0.2 eV. Alternatively, a second hole injection layer is included, and the difference between the top energy level of the valence band of the material of the hole transport layer and the work function of the second hole injection material in the second hole injection layer is less than −0.2 eV. This improves the hole utilization rate in the device, finely regulates the hole injection rate, balances the carrier injection in the device, and improves the recombination efficiency; at the same time, the impact of charge accumulation in the interface layer on the device life is reduced.

In the optoelectronic devices provided in the tenth to thirteenth aspects of the present application, an electron transport layer may also be included, and the electron transport layer includes at least two sub-electron transport layers stacked with each other; the material of at least one sub-electron transport layer is a metal-chalcogenide transport material. Alternatively, the material of at least one sub-electron transport layer is an organic transport material. Alternatively, at least one sub-electron transport layer of a metal-chalcogenide transport material and one sub-electron transport layer material of an organic transport material are included.

In the above embodiments of the present application, the device is not limited by the structure thereof, and may be a device with a regular structure or a device with an inverted structure.

In one embodiment, the regular structure optoelectronic device includes a laminated structure of an anode and a cathode disposed opposite to each other, and a light-emitting layer disposed between the anode and the cathode, and the anode is disposed on a substrate. Hole functional layers such as a hole injection layer and a hole transport layer may also be disposed between the anode and the light-emitting layer; electronic function layers such as an electron transport layer and an electron injection layer may also be disposed between the cathode and the light-emitting layer, as shown in FIG. 14. In some specific embodiments of a device with the regular structure, the optoelectronic device includes a substrate, an anode disposed on the surface of the substrate, a hole transport layer disposed on the surface of the anode, a light-emitting layer disposed on the surface of the hole transport layer, an electron transport layer disposed on the surface of the light-emitting layer, and a cathode disposed on the surface of the electron transport layer.

In one embodiment, the optoelectronic device with an inverted structure includes a laminated structure of an anode and a cathode disposed opposite to each other, and a light-emitting layer disposed between the anode and the cathode, and the cathode is disposed on a substrate. Hole functional layers such as a hole injection layer and a hole transport layer can also be disposed between the anode and the light-emitting layer; electron function layers such as an electron transport layer and an electron injection layer can also be disposed between the cathode and the light-emitting layer, as shown in FIG. 15. In some embodiments of a device with the inverted structure, the optoelectronic device includes a substrate, a cathode disposed on the surface of the substrate, an electron transport layer disposed on the surface of the cathode, a light-emitting layer disposed on the surface of the electron transport layer, a hole transport layer disposed on the surface of the light-emitting layer, and an anode disposed on the surface of the hole transport layer.

In some embodiments, the selection of the substrate is not limited, and a rigid substrate or a flexible substrate may be used. In some specific embodiments, the rigid substrate includes, but is not limited to, one or more of glass and metal foil. In some specific embodiments, the flexible substrate includes, but is not limited to, one or more of polyethylene terephthalate (PET), polyethylene naphthalate (PEN), polyether ether ketone (PEEK), polystyrene (PS), poly(ether-sulfone) (PES), polycarbonate (PC), poly(alkylene terephthalate) (PAT), polyarylate (PAR), polyimide (PI), polyvinyl chloride (PV), polyethylene (PE), polyvinylpyrrolidone (PVP), and textile fibers.

In some embodiments, the choice of anode material is not limited, and may be one or more selected from doped metal oxides, including but not limited to, indium-doped tin oxide (ITO), fluorine-doped tin oxide (FTO), antimony-doped tin oxide (ATO), aluminum-doped zinc oxide (AZO), gallium-doped zinc oxide (GZO), indium-doped zinc oxide (IZO), magnesium-doped zinc oxide (MZO), aluminum-doped magnesium oxide (AMO). It may also be one or more selected from composite electrodes with a metal sandwiched between doped or non-doped transparent metal oxides, including but not limited to, AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂, and TiO₂/Al/TiO₂.

In some embodiments, the cathode material may be one or more of various conductive carbon materials, conductive metal oxide materials, and metal materials. In some specific embodiments, the conductive carbon materials include, but are not limited to, doped or undoped carbon nanotubes, doped or undoped graphene, doped or undoped graphene oxide, C60, graphite, carbon fibers, porous carbon, or mixtures thereof. In some embodiments, the conductive metal oxide materials include, but are not limited to, ITO, FTO, ATO, AZO, or mixtures thereof. In some specific embodiments, the metal materials include, but are not limited to, Al, Ag, Cu, Mo, Au, or their alloys; for the metal materials, the morphology thereof includes but is not limited to dense film, nanowire, nanosphere, nanorods, nano-cones, nano-hollow spheres, or mixtures thereof; the cathode is Ag, Al.

In some embodiments, the quantum dot light-emitting layer has a thickness of 8-100 nm. In some embodiments, the hole transport layer has a thickness of 10-150 nm. In some embodiments, the electron transport layer has a thickness of 10-200 nm. In practical applications, the electronic functional layer, the light-emitting layer, and the hole functional layer in the device can be designed with appropriate thicknesses according to the characteristics of the devices in the above embodiments.

The preparation of the optoelectronic device of the embodiments of the present application includes steps S10-S50:
S10: obtaining a substrate deposited with an anode;
S20: forming a hole injection layer on the surface of the anode;
S30: forming a hole transport layer on the surface of the hole injection layer;
S40: depositing a quantum dot light-emitting layer on the hole transport layer; and
S50: depositing an electron transport layer on the quantum dot light-emitting layer, and evaporating a cathode on the electron transport layer to obtain an optoelectronic device.

Specifically, in step S10, the ITO substrate needs to undergo a pretreatment process. The step includes: cleaning an ITO conductive glass with a detergent to initially remove the stains existing on the surface, and then successively washing it in deionized water, acetone, absolute ethanol, and deionized water; performing ultrasonic cleaning for 20 min to remove the impurities on the surface, and finally drying with high-purity nitrogen to obtain the ITO cathode.

Specifically, in step S20, the step of forming the hole injection layer includes: preparing metal oxide and other materials into a thin film in the QLED device by means of solution method, vacuum sputtering method, and vacuum evaporation method; the solution method includes inkjet printing, spin coating, spray printing, slot-die printing or screen printing, etc.

Specifically, in step S30, the step of forming the hole transport layer includes: placing the ITO substrate on a spin coater, and spin-coating the prepared hole transport material solution to form a thin film; controlling the film thickness by adjusting the concentration of the solution, the spin coating speed and spin coating time, and then performing a thermal annealing treatment at an appropriate temperature.

Specifically, in step S40, the step of depositing the quantum dot light-emitting layer on the hole transport layer includes: placing the substrate on which the hole transport layer has been spin-coated on a spin coater, and spin-coating a solution of the light-emitting substance prepared with a certain concentration to form a film, controlling the thickness of the light-emitting layer by adjusting the concentration of the solution, the spin-coating speed and the spin-coating time, with the thickness of about 20-60 nm, and drying at an appropriate temperature.

Specifically, in step S50, the step of depositing the electron transport layer on the quantum dot light-emitting layer includes: placing the substrate that has been spin-coated with the quantum dot light-emitting layer on a spin coater, and spin-coating a solution of the electron transport composite material prepared with a certain concentration to form a film by drip coating, spin coating, soaking, coating, printing, evaporation and the like, and controlling the thickness of the electron transport layer by adjusting the concentration of the solution, the spin coating speed (for example, the rotation speed between 3000-5000 rpm) and the spin coating time, with the thickness of the electron transport layer of about 20-60 nm, and then annealing at 150° C.-200° C. to form a film to fully remove the solvent.

Specifically, the step of preparing the cathode includes: placing the substrate on which each functional layer has been deposited in an evaporation chamber and thermally evaporating a layer of metallic silver or aluminum of 60-100 nm through a mask plate as the cathode.

In some embodiments, the method for preparing an optoelectronic device further includes encapsulating the optoelectronic device prepared by lamination; the curing resin used in the encapsulation is acrylic resin, acrylic resin, or epoxy resin; the resin is cured by UV irradiation, heat, or a combination of the two. The encapsulation process can adopt common machine encapsulation or manual encapsulation. In the encapsulation environment, the oxygen content and water content are both lower than 0.1 ppm to ensure the stability of the device.

In some embodiments, the preparation method of the optoelectronic device further includes, after the optoelectronic device is encapsulated, introducing one or more processes including ultraviolet irradiation, heating, positive and negative pressure, applied electric field, and applied magnetic field; and the atmosphere may be air or an inert atmosphere.

In order to make the above-mentioned implementation details and operations of the present application clearly understood by those skilled in the art, and to reflect the remarkable performance of the optoelectronic devices of the embodiments of the present application, the above technical proposals are illustrated below through multiple examples.

The device in the examples of the present application adopts a structure of ITO/HIL/HTL/QD/ETL/AL, and is subjected to a certain heat treatment after encapsulation. By comparing the combinations of different functional layers in the device, the advantages of the technical proposal of the present application are explained in detail. In the following examples, the test of the lifetimes adopted the constant current method, and under a constant current of 50 mA/cm², the brightness change of the device was tested by the silicon photonics system, and the brightness of the device was recorded from the highest point to the time LT95 when the brightness decays to 95% of the highest brightness. Then the empirical formula was used to extrapolate the device's 1000 nit LT95S life. This method is convenient for comparing the lifetimes of devices with different brightness levels, and is widely used in practical optoelectronic devices.

1000nit LT95=(L_{Max}/1000)^{1.7}×LT95

Test methodology of the energy level of the materials in the embodiments of the present application: after spin-coating the materials of each functional layer to form a film, the energy level test was performed by UPS (ultraviolet photoelectron spectroscopy).

Work function Φ=Φ=hν−E_{cutoff}, where hν is the energy of the incident excitation photon, and E_{cutoff} is the cutoff position of the excited secondary electron;

Top valence band VB (HOMO): E_{HOMO}=E^{F-HOMO}+Φ, where E^{F-HOMO} is the difference between the material HOMO (VB) and the Fermi level, corresponding to the starting edge of the first peak appearing at the low binding energy end of the binding energy spectrum;

Conduction band bottom (LOMO): E_{LOMO}=E_{HOMO}−E^{HOMO-LOMO}, where E^{HOMO-LOMO} is the band gap of the material, obtained from UV-Vis (ultraviolet absorption spectrum).

### Examples 1-7

In order to verify the effect of the hole injection barrier between the outer shell material of the quantum dot material and the hole transport material on the performance of the device, Examples 1 to 7 were set up in the present application, and the effect of the hole injection barrier on device lifetime and other performance were illustrated through the comparison of different combinations of HTLs and QDs.

Two types of quantum dots were adopted in the Examples 1-7 of the present application: blue QD1 with an outer shell of CdZnS (the core was CdZnSe, the intermediate shell was ZnSe, the outer shell thickness was 1.5 nm, and the energy level of top of the valence band was −6.2 eV), blue QD2 with an outer shell of ZnS (the core was CdZnSe, the intermediate shell was ZnSe, the thickness of the ZnS shell was 0.3 nm, and the top energy level of the valence band was 6.5 eV), and blue QD3 with an outer shell of ZnSeS (the core was CdZnSe, the intermediate shell was ZnSe), the hole transport materials were respectively P9 (E_{HOMO}: 5.1 eV) and P15 (E_{HOMO}: 5.8 eV), and the hole injection layer was made of PEDOT:PSS (E_{HOMO}: 5.1 eV), the electron transport layer was ZnO, as shown in Table 1 below:

TABLE 1

| | Outer shell | | Material of | | | 1000 nit |
|---|---|---|---|---|---|---|
| Device | of blue | | hole transport | | ΔE_{EML-HTL} | LT95 |
| number | quantum dot | | layer | | (eV) | (hour) |
| Example 1 | CdZnS | (6.2 eV) | P15 | (5.8 eV) | 0.4 | 0.72 |
| Example 2 | CdZnS | (6.2 eV) | P9 | (5.1 eV) | 1.1 | 1.26 |
| Example 3 | ZnS | (6.5 eV) | P15 | (5.8 eV) | 0.7 | 6.29 |
| Example 4 | ZnSeS | (6.3 eV) | P15 | (5.8 eV) | 0.5 | 6.26 |
| Example 5 | ZnS | (6.5 eV) | P11 | (5.5 eV) | 1.0 | 11.82 |
| Example 6 | ZnS | (6.5 eV) | P9 | (5.1 eV) | 1.4 | 35.2 |
| Example 7 | ZnS | (6.5 eV) | P13 | (5.1 eV) | 1.6 | 31.2 |

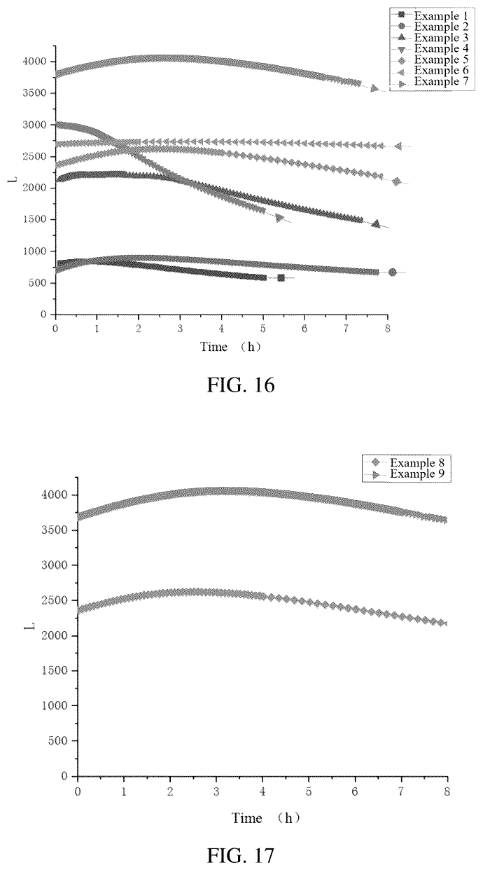

From Table 1 above and FIG. 16 (the horizontal axis is time and the vertical axis is brightness), it can be seen that for the same CdZnS (6.2 eV) outershell quantum dot, when changing the HTL from P15 (5.8 eV) to P9 (5.1 eV), The ΔE_{EML-HTL} barrier difference increased from 0.4 eV to 1.1 eV, the lifetime of the device was improved, and the lifetime of 1000 nit LT95S was increased from 0.72 to 1.26. In addition, for the same P15 (5.8 eV) material, by changing the quantum dot shell from CdZnS (6.2 eV) to ZnS (6.5 eV), the ΔE_{EML-HTL} barrier difference increased from 0.4 eV to 0.7 eV, and the device life was significantly improved, as 1000 nit LT95S lifetime increased from 0.72 to 6.29.

It can be seen that no matter the HTL or EML material is adjusted, as the top energy level difference ΔE_{EML-HTL} between the valence bands was increased to more than 0.5 eV, the device injection balance was optimized, and the device lifetime can be enhanced. It shows that by increasing the hole injection barrier to reduce the hole injection efficiency, the injection balance of holes and electrons in the light-emitting layer can be better balanced, and the luminous efficiency and luminous lifetime of the device can be improved.

### Examples 8-11

In order to verify the influence of the interface energy barrier from HIL to HTL on the performance of the device, Examples 8-11 were set up to illustrate the effect of ΔE_{HTL-HIL} hole injection barrier on the device life through the comparison of different combinations of HTLs and HTLs.

The blue quantum dots with the outer shell of ZnS (the core of CdZnSe, the intermediate shell of ZnSe, the shell thickness of 0.3 nm, and the valence band top energy level of 6.5 eV) were adopted in Examples 8-9 of the present application. Red quantum dots with outer shell of ZnS (core of CdZnSe, the intermediate shell of ZnSe, the outer shell thickness of 0.3 nm, the valence band top energy level of 6.5 eV) were adopted in Examples 10-11, the hole transport materials were P9 (E_{HOMO}: 5.5 eV), P11 (E_{HOMO}: 5.5 eV), P13 (E_{HOMO}: 4.9 eV), the hole injection layer was PEDOT:PSS (E_{HOMO}: 5.1 eV) and HIL2 (work function: 5.6 eV), the electron transport layer was ZnO, as shown in Table 2 below:

TABLE 2

| | Outer shell | Hole | | Hole | | |
|---|---|---|---|---|---|---|
| Device | of blue | transport | | injection | ΔE_{HTL-HIL} | LT95 |
| number | quantum dots | layer | | layer | (eV) | (h) |
| Example 8 | ZnS (6.5 eV) | P11 | (5.5 eV) | PEDOT:PSS | 0.4 | 11.82 |
| Example 9 | ZnS (6.5 eV) | P13 | (4.9 eV) | (5.1 eV) | −0.2 | 31.2 |
| Example 10 | ZnS (6.5 eV) | P9 | (5.1 eV) | | 0.0 | 1094.78 |
| Example 11 | ZnS (6.5 eV) | P9 | (5.1 eV) | HIL 2 | −0.5 | 12221.49 |
| | | | | (5.6 eV) | | |

Note: When ΔE_{HTL-HIL}<0.2 eV, under the existing HIL materials and experimental data, ΔE_{EML-HTL} must be greater than 0.5 eV.

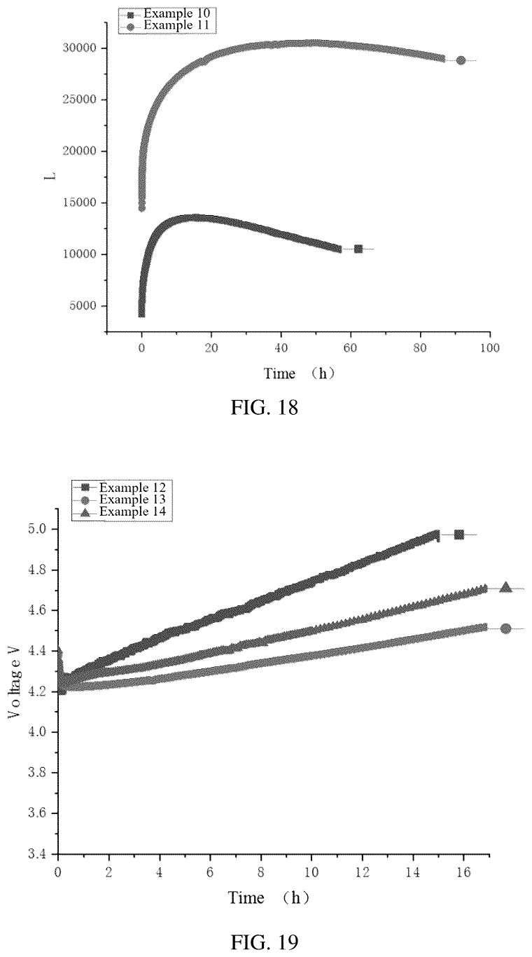

From the test results of the above Table 2 and FIGS. 17 and 18 (the horizontal axis is time, and the vertical axis is brightness), it can be seen that the blue quantum dot devices of Examples 8 and 9 are compared, and the red quantum dot devices of Examples 10 and 11 are compared, for the hole injection barrier between HTL and HIL ΔE_{HTL-HIL}<−0.2 eV, compared with the examples in which ΔE_{HTL-HIL} was greater than or equal to −0.2 eV, the device lifetime 1000 nit LT95S was improved. It shows that increasing the hole injection barrier from the anode to the HIL reduces the overall rate of hole injection in the QLED device and effectively controls the number of holes entering the QLED device, which not only improves the carrier recombination efficiency; but also reduces charge accumulation at the interface between HTL and HIL due to excessive hole injection, which improves the luminous lifetime of the device.

### Examples 12-19

In order to verify the influence of the interface energy barrier from HIL to HTL on the device performance, Examples 12 to 19 were set up to illustrate the influence of the hole injection barrier, |ΔE_{HTL-HIL}| on performances such as device driving voltage by comparing different combinations of HTLs and HTLs.

Blue quantum dots with the outer shell of ZnS (the core of CdZnSe, the intermediate layer of ZnSe, the thickness of the outer shell of 0.3 nm, and the top energy level of the valence band of 6.5 eV) were adopted in Examples 12-14 of the present application, and red quantum dots with outer shell of ZnS (the core of CdZnSe, the intermediate layer of ZnSe, the outer shell thickness of 0.3 nm, the valence band top energy level of 6.5 eV) were adopted in Examples 15-19, the hole transport materials were respectively P9(E_{HOMO}: 5.5 eV), P13 (E_{HOMO}: 4.9 eV), TFB (E_{HOMO}: 5.4 eV), the hole injection layer was PEDOT:PSS (E_{HOMO}: 5.1 eV), HIL1-1 (work function: 5.4 eV) and HIL1-2 (work function: 5.3 eV), the electron transport layer was ZnO, as shown in Table 3 below:

TABLE 3

| | Outer shell | Material of | | | | | Voltage |
|---|---|---|---|---|---|---|---|
| Device | of blue | hole transport | | Material of hole | | ΔE_{HTL-HIL} | increase |
| number | quantum dot | layer | | Injection Layer | | (eV) | (V) @16 H |
| Example 12 | ZnS(6.5 eV) | TFB(5.4 eV) | | PEDOT:PSS (5.1 eV) | | 0.3 | 0.7 |
| Example 13 | ZnS(6.5 eV) | P9(5.1 eV) | | PEDOT:PSS (5.1 eV) | | 0 | 0.25 |
| Example 14 | ZnS(6.5 eV) | P13 (4.9 eV) | | PEDOT:PSS (5.1 eV) | | −0.2 | 0.4 |
| | Outer shell | Material of | | | | | Voltage |
| Device | of red | hole transport | | Material of hole | | ΔE_{HTL-HIL} | increase |
| number | quantum dot | layer | | Injection Layer | | (eV) | (V) @20 H |
| Example 15 | ZnS (6.5 eV) | TFB | (5.4 eV) | PEDOT:PSS | (5.1 eV) | 0.3 | 1 |
| Example 16 | ZnS (6.5 eV) | P15 | (5.8 eV) | PEDOT:PSS | (5.1 eV) | 0.7 | 1.9 |
| Example 17 | ZnS (6.5 eV) | P15 | (5.8 eV) | HIL2 | (5.6 eV) | 0.2 | 0.3 |
| Example 18 | ZnS (6.5 eV) | TFB | (5.4 eV) | HIL1-1 | (5.4 eV) | 0 | −0.4 |
| Example 19 | ZnS (6.5 eV) | TFB | (5.4 eV) | HIL1-2 | (5.3 eV) | 0.1 | −0.4 |

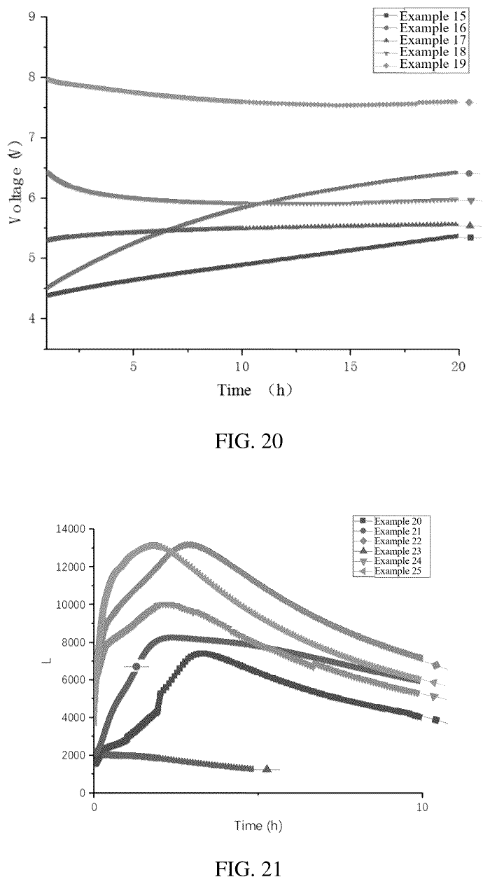

From the above test results of Table 3 and FIGS. 19 and 20 (the horizontal axis is time and the vertical axis is voltage), it can be seen that when the hole injection level barrier |ΔE_{HTL-HIL}| between HTL and HIL was less than or equal to 0.2 eV, compared to the examples where |ΔE_{HTL-HIL} was greater than 0.2 eV, the charge accumulation on the hole transport side of the device was very small, and the driving voltage increase of the device was significantly reduced under operation at the constant current of the device over a long period, and the device life 1000 nit LT95S was improved. At the same time, when the barrier difference between HIL and HTL was small, there was nearly no charge accumulation on the interface, no aging on the opposite side, the hole injection capability of the device was stable, and the lifetime of the device was also improved. It showed that reducing the hole injection barrier was beneficial to the effective injection of holes from HIL to HTL, eliminating the potential barrier and interface charges, reducing the overall resistance of the device, and thus improving the lifetime of the device.

### Examples 20-25

In order to verify the effect of the material of the hole transport layer on the performance of the device, Examples 20 to 25 were set up, and through the comparison of different HTL materials, the effects of HTL materials on building hole injection barriers, optimizing carrier recombination efficiency, and device life are illustrated.

Blue quantum dots with an outer shell of ZnS (the inner core of CdZnSe, the intermediate layer of ZnSe, the outer shell thickness of 0.3 nm, and the top energy level of the valence band of 6.5 eV) were used in Examples 20 to 25 of the present application, and the hole transport materials were respectively P12 (E_{HOMO}: 5.8 eV), P13 (E_{HOMO}: 4.9 eV), TFB (E_{HOMO}: 5.4 eV), and the hole injection layer was PEDOT:PSS (E_{HOMO}: 5.1 eV), as shown in Table 4 below:

TABLE 4

| | Outer shell | | | Electron | |
|---|---|---|---|---|---|
| Device | of blue | Hole transport | HTL hole | transport | LT95 |
| number | quantum dots | layer | mobility | layer | (hr) |
| Example 20 | ZnS (6.5 eV) | P13 (4.9 eV) | 1.70E−03 | Fully | 24.03 |
| | | | | modified and | |
| | | | | passivated | |
| | | | | ZnO | |
| | | | | nanoparticles | |
| Example 21 | | P13 (4.9 eV) | 1.70E−03 | Fully | 28.2 |
| | | P09 (5.1 eV) | 4.00E−03 | modified and | |
| | | | | passivated | |
| | | | | ZnO | |
| | | | | nanoparticles | |
| Example 22 | | P13 (4.9 eV) 50% | 1.70E−03 | Conventional | 76.14 |
| | | TFB (5.4 eV) 50% | 1.00E−03 | ZnO | |
| | | | | nanoparticles | |
| Example 23 | | P12 (5.8 eV) | 3.00E−05 | ZnO | 3.83 |
| | | | | nanoparticles | |
| | | | | with fewer | |
| | | | | surface | |
| | | | | groups | |
| Example 24 | | P13 (4.9 eV) 80% | 1.70E−03 | ZnO | 85.77 |
| | | P12 (5.8 eV) 20% | 3.00E−05 | nanoparticles | |
| | | | | with fewer | |
| | | | | surface | |
| | | | | groups | |
| Example 25 | | P13 (4.9 eV) 40% | 1.70E−03 | Conventional | 64.6 |
| | | TFB (5.4 eV) 40% | 1.00E−03 | ZnO | |
| | | P12 (5.8 eV) 20% | 3.00E−05 | nanoparticles | |

From the above test results of Table 4 and FIG. 21 (the horizontal axis is time and the vertical axis is brightness), it can be seen that materials with different energy levels can be selected to be mixed in the hole transport layer, and the ΔE_{EML-HTL} injection barrier can be flexibly adjusted to build an energy barrier ΔE_{EML-HTL} greater than or equal to 0.5 eV to achieve the purpose of reducing the hole injection rate in QLED devices, regulating the injection and recombination efficiency of carriers, and at the same time reducing the irreversible damage caused by the charge accumulation at the interface between HIL and HTL to the lifetime performance of the device. Moreover, the test results show that the device with the mixed hole transport layer has a better luminous lifetime. The deep energy level of HTL can reduce the brightness change in the life test caused by the exciton transfer in the HTL and QD, and reduce the rising period. Therefore, by mixing the shallow energy level and the deep energy level, the lifetime of the device can be ensured, while the rising period of the brightness of the device can be reduced, and the device can quickly enter a stable state, which is beneficial to subsequent testing and application. Comparing Examples 22, 24 and 25 with reference to FIG. 21, it can be seen from Examples 22 to 24 to 25 that the doping ratio of deep-energy-level materials increased, and the lifetimes were all between 60-80 hrs, with small differences in the lifetimes. The rising period of the brightness were about 7 hrs, 5 hrs, and 4 hrs respectively; compared with Example 21, Examples 22, 24, or 25 had a higher proportion of deep-energy-level materials, and the modulation range of the mobility of the hole transport material was larger and easier. A quantum dot device with a higher lifetime was obtained.

### Examples 26-28

In Examples 26-28, when the shell layer of the blue quantum dot material was ZnS (the core was CdZnSe, the intermediate layer was ZnSe, and the thickness of the shell layer was 0.2-2.0 nm), in order to construct a suitable energy level barrier ΔE_{EML-HTL}, the absolute value of the top energy level of the valence band of the hole transport material must be less than or equal to 6.0 eV, as shown in Examples 26-28 in Table 5 below (the hole injection layer was PEDOT:PSS (E_{HOMO}: 5.1 eV), the electron transport layer was ZnO):

TABLE 5

| | Outer shell | Material of | | | | |
|---|---|---|---|---|---|---|
| Device | of blue | hole transport | | HTL | ΔE_{EML-HTL} | LT95 |
| number | quantum dots | layer | | mobility | (eV) | (hr) |
| Example 26 | ZnS (6.5 eV) | P15 | (5.8 eV) | 1.0E−4 | 0.7 | 6.29 |
| Example 27 | ZnS (6.5 eV) | P11 | (5.5 eV) | 1.3E−3 | 1 | 11.82 |
| Example 28 | ZnS (6.5 eV) | P13 | (4.9 eV) | 1.7E−3 | 1.6 | 31.2 |

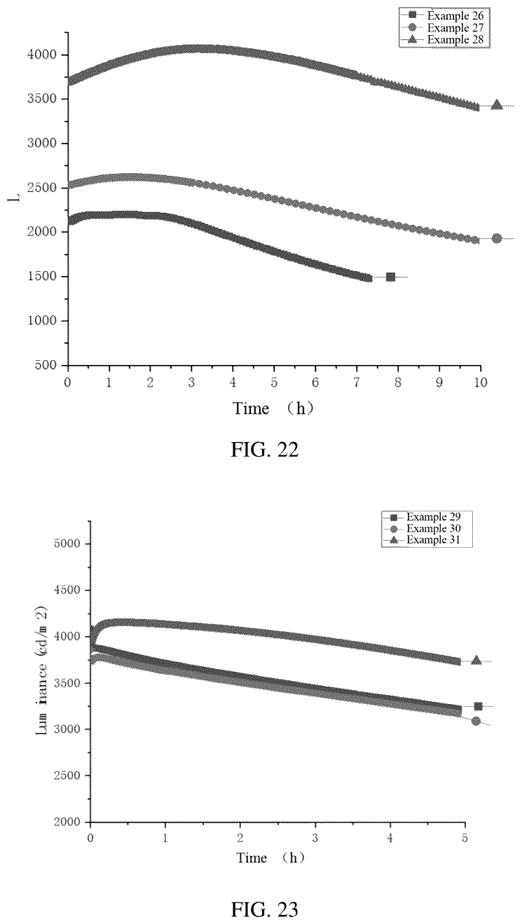

From the test results of the above Table 5 and FIG. 22 (the horizontal axis is time and the vertical axis is brightness), it can be seen that when the outer shell layer of the quantum dot light-emitting layer material was ZnS, and the outer shell thickness was 0.2-2.0 nm, the valence band top energy level difference (ΔE_{EML-HTL}) of the hole transport layer material and the quantum dot outer shell material in the quantum dot light-emitting layer ranged from 1.0 eV to 1.6 eV, and the device showed a better luminous lifetime.

### Examples 29-31

In Examples 29-31, when the shell layer of the blue quantum dot material was ZnSe (the core was CdZnSe, the intermediate layer was ZnSe, and the thickness of the shell layer was 2-5 nm, in order to construct a suitable energy barrier ΔE_{EML-HTL}, the absolute value of the top energy level of the valence band of the hole transport material must be less than or equal to 5.4 eV, as shown in Examples 29-31 in Table 6 below (the hole injection layer was PEDOT:PSS (E_{HOMO}: 5.1 eV), the electron transport layer was ZnO):

TABLE 6

| | Outer shell | Material of | | | | |
|---|---|---|---|---|---|---|
| Device | of blue | hole transport | | HTL | ΔE_{EML-HTL} | LT95 |
| number | quantum dots | layer | | mobility | (eV) | (hr) |
| Example 29 | ZnSe (5.9 eV) | P11 | (5.5 eV) | 1.3E−0.3 | 0.4 | 0.85 |
| Example 30 | ZnSe (5.9 eV) | TFB | (5.4 eV) | 1.0E−0.3 | 0.5 | 7.81 |
| Example 31 | ZnSe (5.9 eV) | P13 | (4.9 eV) | 1.7E−0.3 | 1.0 | 31.3 |

From the test results of the above Table 6 and FIG. 23 (the horizontal axis is time and the vertical axis is brightness), it can be seen that when the outer shell layer of the quantum dot light-emitting layer material was ZnS and the thickness of the outer shell layer was 2-5 nm, the valence band top energy level difference (ΔE_{EML-HTL}) of the hole transport layer material and the quantum dot outer shell material in the quantum dot light-emitting layer ranged from 0.5 eV to 1.0 eV, and the device showed a better luminous lifetime.

### Examples 32-35

In Examples 32-35, when the shell layer of the blue quantum dot material was CdZnS (the core was CdZnSe, the intermediate layer was ZnSe, and the thickness of the shell layer was 0.5-3.0 nm), in order to construct a suitable energy barrier ΔE_{EML-HTL}, the absolute value of the valence band top energy level of the hole transport material must be less than or equal to 5.9 eV, as shown in Examples 32 to 35 in Table 7 below (the hole injection layer was PEDOT:PSS (E_{HOMO}:5.1 eV), the electron transport layer was ZnO):

TABLE 7

| | Outer shell of | Material of | | | | |
|---|---|---|---|---|---|---|
| Device | blue quantum | hole transport | | HTL | ΔE_{EML-HTL} | LT95 |
| number | dots | layer | | mobility | (eV) | (hr) |
| Example 32 | CdZnS (6.3 eV) | P15 | (5.8 eV) | 1.0E−04 | 0.5 | 0.72 |
| Example 33 | CdZnS (6.3 eV) | P9 | (5.1 eV) | 4.0E−03 | 1.2 | 1.26 |
| Example 34 | CdZnS (6.3 eV) | P13 | (4.9 eV) | 1.7E−03 | 1.4 | 7.72 |
| Example 35 | CdZnS (6.3 eV) | P11 | (5.5 eV) | 1.3E−03 | 0.8 | 1.08 |

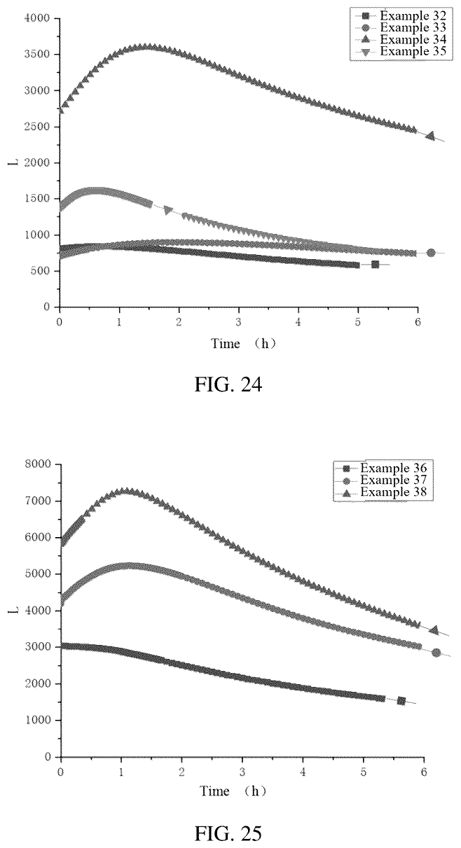

From the test results of the above Table 7 and FIG. 24 (the horizontal axis is time and the vertical axis is brightness), it can be seen that when the outer shell layer of the quantum dot light-emitting layer material was CdZnS and the thickness of the outer shell layer was 0.5-3.0 nm, the valence band top energy level difference (ΔE_{EML-HTL}) of the hole transport layer material and the quantum dot outer shell material in the quantum dot light-emitting layer was in the range of 0.8-1.4 eV, the device showed a better luminous lifetime.

### Examples 36-38

In Examples 36-38, when the shell layer of the blue quantum dot material was ZnSeS (the core was CdZnSe, the intermediate layer was ZnSe, and the thickness of the shell layer was 1.0-4.0 nm), in order to construct a suitable energy barrier ΔE_{EML-HTL}, the absolute value of the valence band top energy level of the hole transport material must be less than or equal to 5.7 eV, as shown in Examples 36 to 38 in Table 8 below (the hole injection layer was PEDOT:PSS (EHOMO: 5.1 eV), the electron transport layer was ZnO):

TABLE 8

| | Outer shell of | Material of | | | | |
|---|---|---|---|---|---|---|
| Device | blue quantum | hole transport | | HTL | ΔE_{EML-HTL} | LT95 |
| number | dots | layer | | mobility | (eV) | (hr) |
| Example 36 | ZnSeS (6.3 eV) | P15 | (5.8 eV) | 1.0E−04 | 0.5 | 6.26 |
| Example 37 | | TFB | (5.4 eV) | 1.0E−0.3 | 0.9 | 13.89 |
| Example 38 | | P13 | (4.9 eV) | 1.7E−03 | 1.4 | 17.62 |

From the test results of the above Table 8 and FIG. 24 (the horizontal axis is time and the vertical axis is brightness), it can be known that when the outer shell layer of the quantum dot light-emitting layer material was CdZnS and the thickness of the outer shell layer was 0.5-3.0 nm, the valence band top energy level difference (ΔE_{EML-HTL}) of the hole transport layer material and the quantum dot outer shell material in the quantum dot light-emitting layer was in the range of 0.9-1.4 eV, the device showed a better luminous lifetime.

### Examples 39-43

In order to verify the effect of the hole injection layer on the performance of the device, the present application provides the following examples. In Examples 39-41, the red quantum dots with the outer shell of ZnS (the core of CdZnSe, the intermediate layer of ZnSe, and the energy level at the top of the valence band of 6.5 eV) were used. In Examples 42-43, red quantum dots with an outer shell of ZnS (the core of CdZnSe, the intermediate layer of ZnSe, and the valence band top energy level of 6.5 eV) were used, and the electron transport layer was ZnO. As shown in Table 9:

TABLE 9

| | Outer shell | Material | Mobility | Material | | |
|---|---|---|---|---|---|---|
| | of red | of hole | of hole | of hole | | Voltage |
| Device | quantum | transport | transport layer | Injection | T95 | increase |
| number | dots | layer | material | Layer | (hr) | (V) @40 H |
| Example 39 | ZnS(6.5 eV) | TFB | 1.00E−03 | PEDOT:PSS | 2000 | 1.5 |
| | | (5.4 eV) | | (5.1 eV) | | |
| Example 40 | ZnS(6.5 eV) | TFB | 1.00E−03 | none | 162.5 | −0.3 |
| | | (5.4 eV) | | | | |
| Example 41 | ZnS(6.5 eV) | P11 | 1.30E−03 | none | 1436 | −0.15 |
| | | (5.5 eV) | | | | |

| | Outer shell | Material | Mobility | Material | | Voltage |
|---|---|---|---|---|---|---|
| | of red | of hole | of hole | of hole | | increase |
| Device | quantum | transport | transport layer | Injection | T95 | (V) (Lₘₐₓ to |
| number | dots | layer | material | Layer | (h) | L95 |
| Example 42 | ZnS(6.5 eV) | TFB | 1.00E−03 | MoO₃ | 2357 | −0.2 |
| | | (5.4 eV) | | | | |
| Example 43 | ZnS(6.5 eV) | TFB | 1.00E−03 | PEDOT:PSS | 2000 | 0.8 |
| | | (5.4 eV) | | (5.1 eV) | | |

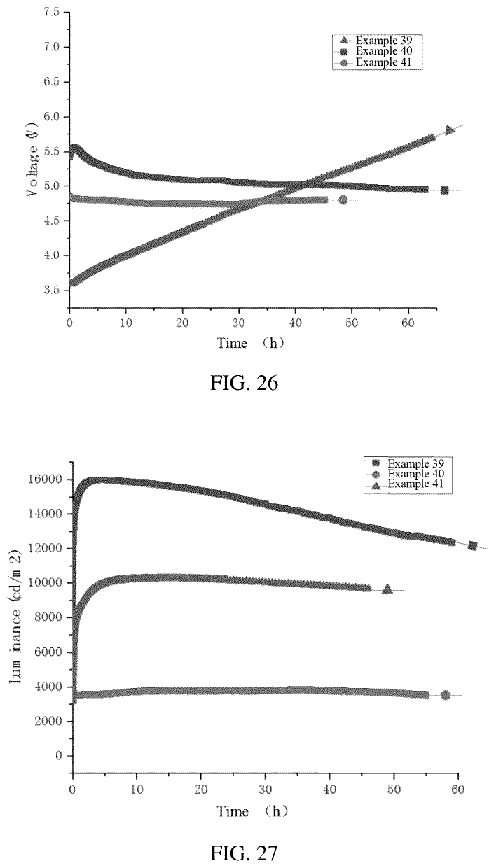

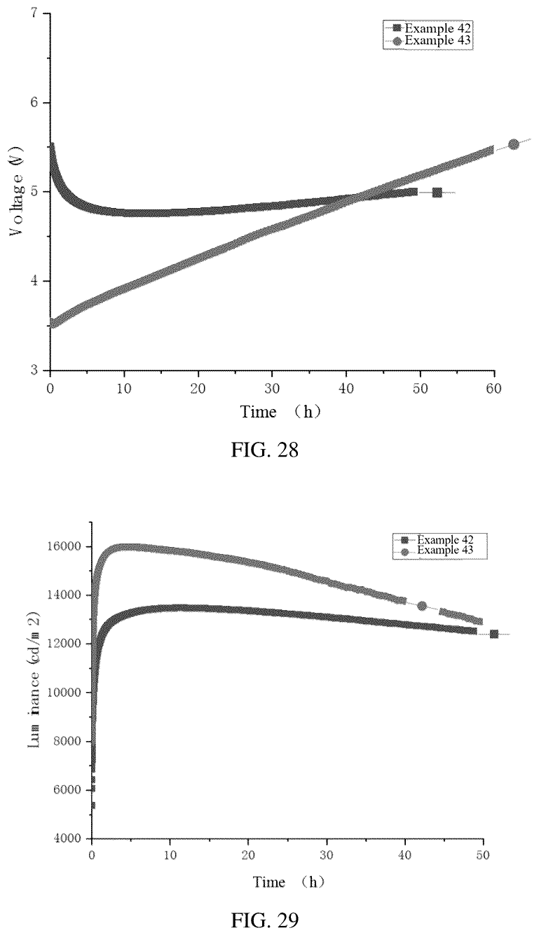

From the test results of the above Table 9 and FIGS. 26 and 28 (the horizontal axis is time and the vertical axis is brightness), and FIGS. 27 and 29 (the horizontal axis is time and the vertical axis is brightness), it can be known that when the HIL layer was removed from the device, the fluence of the charge accumulation between the hole injection layer and the hole transport layer and the influence of acidic PEDOT on the device disappeared, and the driving voltage of the device was almost unchanged under the long-term constant current operation of the device There was even a tendency for the device drive voltage to drop as the charge fills the defects within the device. By using P11 with higher mobility to prepare HIL-free devices, the device's driving voltage dropped more significantly under long-term constant current operation, indicating that the HTL mobility was higher than 1×10⁻³ cm²/Vs, and better suppressing effect on voltage increase of the devices can be obtained

In addition, when the inorganic metal oxide MoO₃ was used instead of the organic PEDOT:PSS as the material of the hole injection layer, since the damage of the hole injection material of MoO₃ was effectively suppressed, the voltage rise of the device during operation was significantly lower than that of the devices with the organic hole injection layer material, and the measured duration of the device life was also effectively improved.

The above are only the preferred embodiments of the present application, not to limit the present application, any modifications, equivalent substitutions and improvements made without departing from the spirit and principles of the present application are within the scope of protection of in the present application.

1. An optoelectronic device, comprising an anode, a hole transport layer disposed on the anode, a quantum dot light-emitting layer disposed on the hole transport layer, and a cathode disposed on the quantum dot light-emitting layer;
wherein the quantum dot light-emitting layer comprises a quantum dot material in a core-shell structure, and a top energy level difference between a valence band of an outer shell layer material of the quantum dot material and a valence band of a hole transport material in the hole transport layer ranges from 0.5 eV to 0.7 eV.

2. (canceled)

3. An optoelectronic device, comprising an anode, a hole transport layer disposed on the anode, a quantum dot light-emitting layer disposed on the hole transport layer, and a cathode disposed on the quantum dot light-emitting layer;
wherein the quantum dot light-emitting layer comprises a quantum dot material in a core-shell structure, and wherein a top energy level difference between a valence band of an outer shell layer material of the quantum dot material and a valence band of a hole transport material in the hole transport layer ranges from 0.7 eV to 1.0 eV.

4. (canceled)

5. An optoelectronic device, comprising an anode, a hole transport layer disposed on the anode, a quantum dot light-emitting layer disposed on the hole transport layer, and a cathode disposed on the quantum dot light-emitting layer;
wherein the quantum dot light-emitting layer comprises a quantum dot material in a core-shell structure, and wherein a top energy level difference between a valence band of an outer shell layer material of the quantum dot material and a valence band of a hole transport material in the hole transport layer ranges from 1.4 eV to 1.7 eV.

6. The optoelectronic device according to claim 1, wherein the optoelectronic device comprises a first hole injection layer, the first hole injection layer is located between the anode layer and the hole transport layer, and an absolute value of a difference between the top energy level of the valence band of the hole transport layer material and a work function of a first hole injection material in the first hole injection layer is less than or equal to 0.2 eV.

7. The optoelectronic device according to claim 6, wherein an absolute value of the work function of the first hole injection material ranges from 5.3 eV to 5.6 eV; and/or
wherein the absolute value of the difference between the top energy level of the valence band of the hold transport layer material and the work function of the first hole injection material is 0 eV.

8. (canceled)

9. The optoelectronic device according to claim 1, wherein the optoelectronic device comprises a second hole injection layer, the second hole injection layer is located between the anode layer and the hole transport layer, and a difference between the top energy level of the valence band of the hole transport layer material and a work function of a second hole injection material in the second hole injection layer is less than −0.2 eV.

10. The optoelectronic device according to claim 9, wherein an absolute value of the work function of the second hole injection material ranges from 5.4 eV to 5.8 eV; and/or
wherein the difference between the top energy level of the valence band of the hole transport layer material and the work function of the second hole injection material ranges from −0.9 eV to −0.2 eV.

11. (canceled)

12. The optoelectronic device according to claim 7, wherein the first hole injection material in the first hole injection layer is selected from a first metal oxide material.

13. The optoelectronic device according to claim 10, wherein the second hole injection material in the second hole injection layer is selected from a second metal oxide material.

14. The optoelectronic device according to claim 12, wherein the first metal oxide material comprises at least one metal nanomaterial of tungsten oxide, molybdenum oxide, vanadium oxide, nickel oxide, and copper oxide; and/or
wherein a particle size of the first metal oxide material ranges from 2 nm to 10 nm; and/or
wherein a thickness of the first hole injection layer ranges from 10 nm to 150 nm.

15. (canceled)

16. (canceled)

17. The optoelectronic device according to claim 13, wherein the second metal oxide material comprises at least one metal nanomaterial of tungsten oxide, molybdenum oxide, vanadium oxide, nickel oxide, and copper oxide; and/or
wherein a particle size of the first metal oxide material ranges from 2 nm to 10 nm; and/or
wherein a thickness of the first hole injection layer ranges from 10 nm to 150 nm.

18. (canceled)

19. (canceled)

20. The optoelectronic device according to claim 1, wherein the hole transport layer comprises at least two hole transport materials, and an absolute value of a top energy level of a valence band of at least one hole transport material is less than or equal to 5.3 eV.

21. The optoelectronic device according to claim 20, wherein in the hole transport layer, the hole transport material having the absolute value of the top energy level of the valence band less than or equal to 5.3 eV has a mass percentage content of 30%-90%; and
wherein, the hole transport layer further comprises a hole transport material having an absolute value of a top energy level of a valence band greater than 5.3 eV and less than 5.8 eV; and/or
wherein the hole transport layer further comprises a hole transport material having an absolute value of a top energy level of a valence band greater than or equal to 5.8 eV.

22. (canceled)

23. The optoelectronic device according to claim 20, wherein an absolute value of a top energy level of a valence band of each hole transport material is less than or equal to 5.3 eV; and
wherein, in the hole transport layer, the each hole transport material has a mass percentage content of 5%-95%.

24. The optoelectronic device according to claim 21, wherein the hole transport material is at least one selected from a polymer containing an aniline group and a copolymer containing a fluorene group and an aniline group; and/or
wherein the hold transport material has a mobility of higher than 1×10⁻⁴ cm²/Vs.

25. (canceled)

26. The optoelectronic device according to claim 24, wherein the hole transport material having the absolute value of the top energy level of the valence band less than or equal to 5.3 eV comprises: at least one of P09 and P13; and/or
wherein the hold transport material having the absolute value of the top energy level of the valence band greater than 5.3 eV and less than 5.8 eV comprises: at least one of TFB, poly-TPD, and P11; and/or
wherein the hold transport material having the absolute value of the top energy level of the valence band greater than or equal to 5.8 eV comprises: at least one of P15 and P12; and/or
wherein the hold transport material has a mobility of higher than 1×10⁻³ cm²/Vs.

27. (canceled)

28. (canceled)

29. (canceled)

30. The optoelectronic device according to claim 1, wherein the optoelectronic device further comprises an electron transport layer, and an electron transport material in the electron transport layer is at least one selected from a metal-chalcogenide transport material and an organic transport material; and
wherein the metal-chalcogenide transport material is at least one selected from titanium oxide, zinc sulfide, and cadmium sulfide; and/or
wherein the metal-chalcogenide transport material is at least one selected from titanium oxide, zinc sulfide, and cadmium sulfide that is doped with a metal element, and the metal element comprises at least one aluminum, magnesium, lithium, lanthanum, yttrium, manganese, gallium, iron, chromium, and cobalt; and/or
wherein the metal-chalcogenide transport material has a particle size less than or equal to 10 nm.

31. (canceled)

32. (canceled)

33. (canceled)

34. (canceled)

35. The optoelectronic device according to claim 30, wherein the organic transport material has an electron mobility of no less than 10⁻⁴ cm²/Vs; and/or
wherein the organic transport material is at least one selected from 8-hydroxyquinoline-lithium, 8-hydroxyquinoline aluminum, fullerene derivative, 3,5-bis(4-tert-butylphenyl)-4-phenyl-4H-1,2,4-triazole, 1,3,5-tris(1-phenyl-1H-benzimidazol-2-yl)benzene.

36. (canceled)

37. The optoelectronic device according to claim 35, wherein, when the hole transport layer further comprises a hole transport material having an absolute value of a top energy level of a valence band greater than 5.3 eV and less than 5.8 eV, the electron transport layer comprises: at least one of an organic electron transport material layer, a metal oxide nanoparticle layer, and a sputter-deposited metal oxide layer;
wherein when the hole transport layer further comprises a hole transport material having an absolute value of a top energy level of a valence band greater than or equal to 5.8 eV, the electron transport layer comprises metal oxide nanoparticles; and
wherein when an absolute value of a top energy level of a valence band of each hole transport material is less than or equal to 5.3 eV, the electron transport layer comprises surface passivated metal oxide nanoparticles.

38. The optoelectronic device according to claim 30, wherein the electron transport layer has a laminated composite structure, which comprises at least two sub-electron transport layers; and
wherein at least one sub-electron transport layer in the electron transport layer is made of an organic transport material.

39. (canceled)

40. (canceled)

41. (canceled)

42. (canceled)

43. (canceled)

44. (canceled)

45. (canceled)

46. (canceled)

47. (canceled)

48. (canceled)

49. (canceled)
